(19) United States
(12) Patent Application Publication
(10) Pub. No.: US 2024/0258483 A1
(43) Pub. Date: Aug. 1, 2024

(54) DISPLAY DEVICE AND METHOD OF MANUFACTURING THE SAME

(71) Applicant: Samsung Display Co., LTD., Yongin-si (KR)

(72) Inventors: Hyun Deok IM, Yongin-si (KR); Jong Hyuk KANG, Yongin-si (KR); Soo Jo OCK, Yongin-si (KR); Won Ho LEE, Yongin-si (KR)

(21) Appl. No.: 18/419,086

(22) Filed: Jan. 22, 2024

(30) Foreign Application Priority Data
Jan. 26, 2023 (KR) 10-2023-0010445

(51) Int. Cl. H01L 33/62; H01L 25/16; H01L 33/48

(52) U.S. Cl. CPC H01L 33/62; H01L 25/167; H01L 33/483; H01L 2933/0066

(57) ABSTRACT

According to one or more embodiments of the present disclosure, a display device may include a substrate including a first emission area and a second emission area spaced from the first emission area in a first direction, a bank partitioning the first emission area and the second emission area, a first alignment electrode covering the first emission area in a plan view, a second alignment electrode spaced from the second alignment electrode and covering the second emission area in a plan view, first light emitting elements on the first alignment electrode, and second light emitting elements on the second alignment electrode.

### CROSS-REFERENCE TO RELATED APPLICATION

This application claims priority to and the benefit of Korean Patent Application No. 10-2023-0010445, filed on, Jan. 26, 2023, in the Korean Intellectual Property Office, the entire content of which is incorporated by reference herein.

### BACKGROUND

### 1. Field

The present disclosure relates to a display device and a method of manufacturing the same.

### 2. Description of the Related Art

Recently, as interest in information display is increased, research and development of a display device are continuously being conducted.

### SUMMARY

A parasitic electric field due to elements configuring a pixel circuit may occur, and in this case, an electric field formed between alignment electrodes may be distorted by the parasitic electric field. An aspect of the present disclosure is to provide a display device that ensures light emitting efficiency by reducing or minimizing distortion of an electric field formed between alignment electrodes so that light emitting elements may be stably aligned on the alignment electrodes.

Another aspect of the present disclosure is to provide a method of manufacturing the display device.

However, an aspect of the present disclosure is not limited to the above-described aspects, and may be variously expanded without departing from the spirit and scope of the present disclosure.

According to one or more embodiments of the present disclosure, a display device may include a substrate including a first emission area and a second emission area spaced from the first emission area in a first direction, a bank partitioning the first emission area and the second emission area, a first alignment electrode covering the first emission area in a plan view, a second alignment electrode spaced from the first alignment electrode and covering the second emission area in a plan view, first light emitting elements on the first alignment electrode, and second light emitting elements on the second alignment electrode.

According to one or more embodiments, the first alignment electrode is configured to receive a first alignment signal, and the second alignment electrode is configured to receive a second alignment signal, and the first alignment signal may be different from the second alignment signal.

According to one or more embodiments, the display device may further include a third alignment electrode covering a third emission area spaced from the second emission area in the first direction, and third light emitting elements on the third alignment electrode, and when the first to third light emitting elements are aligned, the third alignment electrode is configured to receive the first alignment signal.

According to one or more embodiments, the display device may further include an insulating layer covering the first alignment electrode and the second alignment electrode, and the insulating layer may include at least one first opening overlapping the first emission area, and at least one second opening overlapping the second emission area.

According to one or more embodiments, the first light emitting elements may be on the at least one first opening, and the second light emitting elements may be on the at least one second opening.

According to one or more embodiments, the display device may further include an insulating pattern filling the at least one first opening and the at least one second opening, the first light emitting elements may be directly located on a portion of the insulating pattern, and the second light emitting elements may be directly located on another portion of the insulating pattern.

According to one or more embodiments, each of the first emission area and the second emission area may include a central area and a peripheral area surrounding the central area, the at least one first opening may be in an area corresponding to the central area of the first emission area, and the at least one second opening may be in an area corresponding to the central area of the second emission area.

According to one or more embodiments, the at least one first opening and the at least one second opening may not be in the peripheral area.

According to one or more embodiments, each of the at least one first opening and the at least one second opening may be one opening extending in a second direction crossing the first direction in the central area.

According to one or more embodiments, the at least one first opening includes a plurality of first openings and the at least one second opening may include a plurality of second openings, the first openings may be spaced from each other in a second direction crossing the first direction, and the second openings may be spaced from each other in the second direction.

According to one or more embodiments, the at least one first opening may cross the first emission area along a second direction crossing the first direction.

According to one or more embodiments, each of the at least one first opening and the at least one second opening may be one opening extending in the second direction.

According to one or more embodiments, the at least one first opening includes a plurality of first openings and the at least one second opening may include a plurality of second openings that are spaced from each other, the first openings may be spaced from each other in the second direction, and the second openings may be spaced from each other in the second direction.

According to one or more embodiments, the at least one first opening may include at least one (1-1)-th opening extending in a second direction crossing the first direction, and at least one (1-2)-th opening spaced from the at least one (1-1)-th opening in the first direction, and the at least one second opening may include at least one (2-1)-th opening extending in the second direction, and at least one (2-2)-th opening spaced from the at least one (2-1)-th opening in the first direction.

According to one or more embodiments, a portion of the first light emitting elements may be on the at least one (1-1)-th opening, a rest of the first light emitting elements may be on the at least one (1-2)-th opening, a portion of the second light emitting elements may be on the at least one (2-1)-th opening, and a rest of the second light emitting elements may be on the at least one (2-2)-th opening.

According to one or more embodiments, each of the first light emitting elements and the second light emitting elements may include a first end and a second end opposite the first end, and the first end of the first light emitting elements on the at least one (1-1)-th opening may face the first end of the first light emitting elements on the at least one (1-2)-th opening, in a plan view.

According to one or more embodiments, the first light emitting elements on the at least one (1-2)-th opening may have a same orientation as the second light emitting elements on the at least one (2-1)-th opening.

According to one or more embodiments, a boundary area between the first alignment electrode and the second alignment electrode may be under the bank, and an area of the first alignment electrode may be equal to an area of the second alignment electrode.

According to one or more embodiments, each of the first light emitting elements and the second light emitting elements may include a first end and a second end opposite the first end, and the display device may further include a first pixel electrode, a connection electrode, and a second pixel electrode in each of the first emission area and the second emission area, spaced from each other in the first direction, and sequentially arranged, the first pixel electrode may be connected to the first end of a portion of the first light emitting elements, the connection electrode may connect the second end of the portion of the first light emitting elements and the first end of a rest of the first light emitting elements, and the second pixel electrode may be connected to the second end of the rest of the first light emitting elements.

According to one or more embodiments of the present disclosure, a method of manufacturing a display device may include forming a first alignment electrode covering a first emission area of a substrate and a second alignment electrode covering a second emission area of the substrate spaced from the first emission area in a first direction, forming an insulating layer covering the first and second alignment electrodes, forming at least one first opening exposing the first alignment electrode and at least one second opening exposing the second alignment electrode in the insulating layer, forming a bank on a boundary area between the first alignment electrode and the second alignment electrode, providing light emitting elements to the first emission area and the second emission area, and arranging the first and second light emitting elements by applying a first alignment signal to the first alignment electrode and a second alignment signal different from the first alignment signal to the second alignment electrode.

The display device and the method of manufacturing the same according to one or more embodiments of the present disclosure may shield a parasitic electric field due to a pixel circuit by disposing one alignment electrode per sub-pixel and causing a boundary area between alignment electrodes to overlap a non-emission area. Accordingly, light emitting efficiency may be increased by reducing or minimizing a light emitting element of a defective state (for example, a misaligned state) occurring due to the parasitic electric field.

In addition, the display device and the method of manufacturing the same according to one or more embodiments of the present disclosure may allow an electric field formed between the alignment electrodes to be concentrated in an opening formed in the insulating layer. Accordingly, the light emitting elements may be accurately aligned in the area where the electric field is concentrated, thereby increasing light emitting efficiency.

However, an effect of the present disclosure is not limited to the above-described effect, and may be variously expanded without departing from the spirit and scope of the present disclosure.

### BRIEF DESCRIPTION OF THE DRAWINGS

The above and other aspects and features of the present disclosure will become more apparent by describing in further detail embodiments thereof with reference to the accompanying drawings, in which:

FIG. 1 is a perspective cutaway view schematically illustrating a light emitting element according to one or more embodiments of the present disclosure;

FIG. 2 is a cross-sectional view illustrating an example of the light emitting element of FIG. 1;

FIG. 3 is a schematic plan view illustrating a display device according to one or more embodiments of the present disclosure;

FIG. 4 is a circuit diagram illustrating an embodiment of a sub-pixel included in the display device of FIG. 3;

FIG. 5 is a schematic plan view illustrating an embodiment of a bank partitioning sub-pixels included in the display device of FIG. 3;

FIG. 6 is a schematic plan view illustrating an embodiment of the sub-pixels included in the display device of FIG. 3;

FIG. 7 is a schematic plan view illustrating an embodiment of the sub-pixels included in the display device of FIG. 3;

FIG. 8 is a schematic cross-sectional view illustrating an embodiment taken along the line I-I′ of FIGS. 6 and 7;

FIGS. 9 and 10 are schematic cross-sectional views illustrating another embodiment taken along the line I-I′ of FIGS. 6 and 7;

FIG. 11A is a cross-sectional view illustrating a comparative example of the sub-pixels included in the display device;

FIG. 11B is a schematic cross-sectional view illustrating an embodiment of the sub-pixels included in the display device of FIG. 3;

FIG. 12 is a graph illustrating an electric field intensity on a first insulating layer of FIG. 11B;

FIGS. 13 to 15 are schematic plan views illustrating another embodiment of the sub-pixels included in the display device of FIG. 3; and

FIGS. 16 to 19 are schematic plan views illustrating a method of manufacturing a display device according to one or more embodiments of the present disclosure.

### DETAILED DESCRIPTION

Hereinafter, embodiments of the present disclosure are described in more detail with reference to the accompanying drawings. The same reference numerals are used for the same components in the drawings, and a repeated description of the same components is omitted.

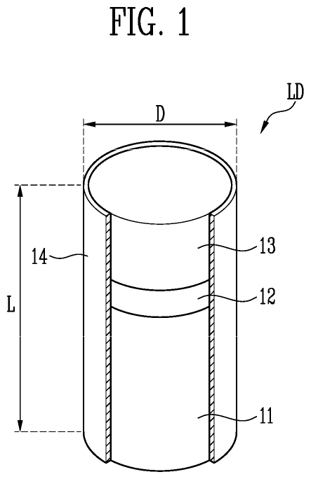

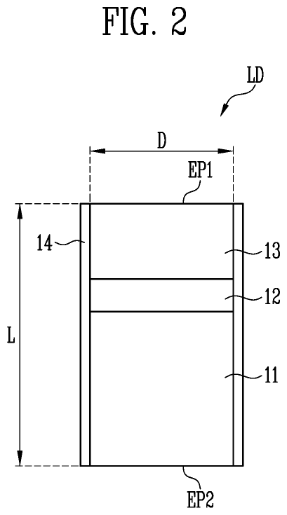

FIG. 1 is a perspective cutaway view schematically illustrating a light emitting element according to one or more embodiments of the present disclosure. FIG. 2 is a cross-sectional view illustrating an example of the light emitting element of FIG. 1.

Referring to FIGS. 1 and 2, the light emitting element LD may include a first semiconductor layer 11, a second semiconductor layer 13, and an active layer 12 interposed between the first semiconductor layer 11 and the second semiconductor layer 13. For example, the light emitting element LD may be implemented in a light emitting stack (or a stack pattern) in which the first semiconductor layer 11, the active layer 12, and the second semiconductor layer 13 are sequentially stacked.

The light emitting element LD may be provided in a shape extending in one direction. When an extension direction of the light emitting element LD is referred to as a length direction, the light emitting element LD may include a first end EP1 and a second end EP2 along the length direction. One semiconductor layer of the first semiconductor layer 11 and the second semiconductor layer 13 may be positioned at the first end EP1 of the light emitting element LD, and the other semiconductor layer of the first semiconductor layer 11 and the second semiconductor layer 13 may be positioned at the second end EP2 of the light emitting element LD.

The light emitting element LD may be provided in various shapes. For example, as shown in FIG. 1, the light emitting element LD may have a rod-like shape, a bar-like shape, or a column shape that is long in the length direction (or having an aspect ratio greater than 1). As another example, the light emitting element LD may have a rod-like shape, a bar-like shape, or a column shape that is short in the length direction (or having an aspect ratio of less than 1). As still another example, the light emitting element LD may have a rod-like shape, a bar-like shape, or a column shape having an aspect ratio of 1.

The light emitting element LD may include, for example, a light emitting diode (LED) manufactured to be extremely small to have a diameter D and/or a length L of about a nano scale (or a nano meter range) to a micro scale (or a micro meter range).

When the light emitting element LD is long in the length direction (that is, the aspect ratio is greater than 1), the diameter D of the light emitting element LD may be about 0.5 μm to 6 μm, and the length L of the light emitting element LD may be about 1 μm to 10 μm. However, the diameter D and the length L of the light emitting element LD are not limited thereto. A size of the light emitting element LD may be changed to satisfy a requirement condition (or a design condition) of a lighting device or a self-emission display device to which the light emitting element LD is applied.

The first semiconductor layer 11 may include, for example, at least one n-type semiconductor layer. The first semiconductor layer 11 may include an upper surface contacting the active layer 12 along the length direction of the light emitting element LD and a lower surface exposed to the outside. The lower surface of the first semiconductor layer 11 may be one end (or a lower end) of the light emitting element LD.

The active layer 12 may be disposed on the first semiconductor layer 11 and may be formed in a single or multiple quantum well structure. For example, when the active layer 12 is formed in the multiple quantum well structure, in the active layer 12, a barrier layer, a strain reinforcing layer, and a well layer may be periodically and repeatedly stacked as one unit. The strain reinforcing layer may have a lattice constant less than that of the barrier layer to further reinforce a strain, for example, a compression strain, applied to the well layer. However, a structure of the active layer 12 is not limited to the above-described embodiment.

The active layer 12 may emit light of a wavelength of about 400 nm to 900 nm, and may use a double hetero structure. The active layer 12 may include a first surface contacting the first semiconductor layer 11 and a second surface contacting the second semiconductor layer 13.

A color (or an output light color) of the light emitting element LD may be determined according to the wavelength of the light emitted from the active layer 12. The color of the light emitting element LD may determine a color of a corresponding pixel. For example, the light emitting element LD may emit red light, green light, or blue light.

When an electric field of a suitable voltage (e.g., a predetermined voltage) or more is applied between both ends of the light emitting element LD, the light emitting element LD emits light while an electron-hole pair is combined in the active layer 12. By controlling light emission of the light emitting element LD by using such a principle, the light emitting element LD may be used as a light source (or a light emitting source) of various light emitting devices including a pixel of the display device.

The second semiconductor layer 13 may be disposed on the second surface of the active layer 12 and may include a semiconductor layer of a type different from that of the first semiconductor layer 11.

The second semiconductor layer 13 may include a lower surface contacting the second surface of the active layer 12 along the length direction of the light emitting element LD and an upper surface exposed to the outside. Here, the upper surface of the second semiconductor layer 13 may be another end (or an upper end) of the light emitting element LD.

The first semiconductor layer 11 and the second semiconductor layer 13 may have thicknesses different from each other in the length direction of the light emitting element LD. For example, the first semiconductor layer 11 may have a thickness relatively greater than that of the second semiconductor layer 13 along the length direction of the light emitting element LD. Therefore, the active layer 12 of the light emitting element LD may be positioned more adjacently to the upper surface of the second semiconductor layer 13 than to the lower surface of the first semiconductor layer 11.

Although the first semiconductor layer 11 and the second semiconductor layer 13 are shown as being configured of one layer, the present disclosure is not limited thereto. In one or more embodiments, according to the material of the active layer 12, each of the first semiconductor layer 11 and the second semiconductor layer 13 may further include at least one or more layers, for example, a clad layer and/or a tensile strain barrier reducing (TSBR) layer. The TSBR layer may be a strain relief layer disposed between semiconductor layers having different lattice structures and serving as a buffer for reducing a lattice constant difference. The TSBR layer may be configured of a p-type semiconductor layer such as p-GaInP, p-AlInP, and p-AlGaInP, but is not limited thereto.

The light emitting element LD may further include a contact electrode (hereinafter referred to as a “first contact electrode”) disposed on the second semiconductor layer 13 in addition to the above-described first semiconductor layer 11, active layer 12, and second semiconductor layer 13. In addition, according to another embodiment, the light emitting element LD may further include another contact electrode (hereinafter referred to as a “second contact electrode”) disposed at one end of the first semiconductor layer 11.

Each of the first and second contact electrodes may be an ohmic contact electrode, but is not limited thereto. According to one or more embodiments, the first and second contact electrodes may be Schottky contact electrodes. The first and second contact electrodes may include a conductive material.

The light emitting element LD may further include an insulating layer 14 (or an insulating film). However, according to one or more embodiments, the insulating layer 14 may be omitted and may be provided so as to cover only a portion of an outer surface (e.g., an outer peripheral or circumferential surface) of the first semiconductor layer 11, the active layer 12, and the second semiconductor layer 13.

The insulating layer 14 may prevent an electrical short that may occur when the active layer 12 contacts a conductive material other than the first and second semiconductor layers 11 and 13. In addition, the insulating layer 14 may 14 may reduce or minimize a surface defect of the light emitting element LD to improve life and light emission efficiency of the light emitting element LD. When the active layer 12 may prevent occurrence of a short with an external conductive material, presence or absence of the insulating layer 14 is not limited.

The insulating layer 14 may be around (e.g., may surround) at least a portion of an outer surface (e.g., an outer peripheral or circumferential surface) of the light emitting stack including the first semiconductor layer 11, the active layer 12, and the second semiconductor layer 13.

In the above-described embodiment, the insulating layer 14 entirely surround the outer surface (e.g., the outer peripheral or circumferential surface) of each of the first semiconductor layer 11, the active layer 12, and the second semiconductor layer 13, but the present disclosure is not limited thereto.

The insulating layer 14 may include a transparent insulating material. For example, the insulating layer 14 may include at least one insulating material selected from a group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), magnesium oxide (MgO), zinc oxide (ZnOₓ), rucenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InxOy:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and vanadium nitride (VN), but the present disclosure is not limited thereto, and various materials having insulating properties may be used as the material of the insulating layer 14.

The insulating layer 14 may be provided in a form of a single layer, or may be provided in a form of multiple layers including double layers.

The above-described light emitting element LD may be used as a light emitting source (or a light source) of various display devices. The light emitting element LD may be manufactured through a surface treatment process. For example, when a plurality of light emitting elements LD are mixed in a fluid solution (or solvent) and supplied to each pixel area (for example, an emission area of each pixel or an emission area of each sub-pixel), surface treatment may be performed on each of the light emitting elements LD so that the light emitting elements LD may be uniformly sprayed without being unevenly aggregated in the solution.

A light emitting unit (or a light emitting device) including the light emitting element LD described above may be used in various types of electronic devices that require a light source, including a display device. For example, when a plurality of light emitting elements LD are disposed in a pixel area of each pixel of a display panel, the light emitting elements LD may be used as a light source of each pixel. However, an application field of the light emitting element LD is not limited to the above-described example. For example, the light emitting element LD may be used in other types of electronic devices that require a light source, such as a lighting device.

However, this is an example, and the light emitting element LD applied to the display device according to one or more embodiments of the present disclosure is not limited thereto. For example, the light emitting element may be a flip chip type of micro light emitting diode or an organic light emitting element including an organic light emitting layer.

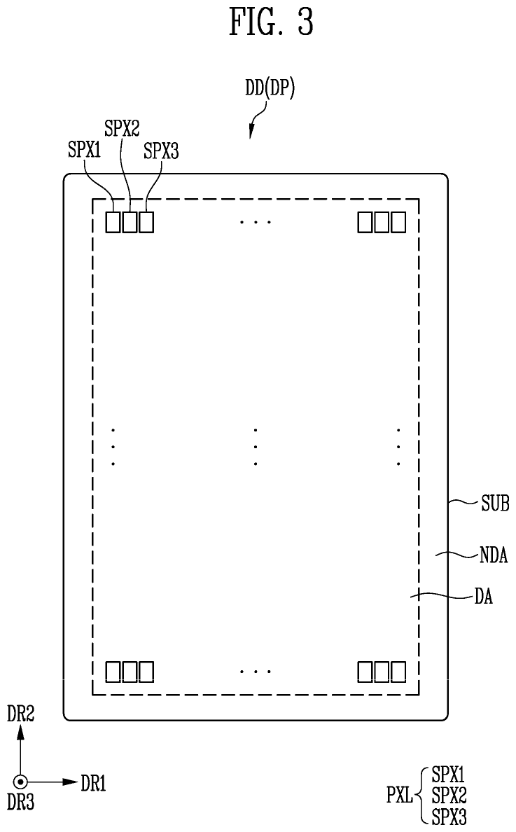

FIG. 3 is a schematic plan view illustrating a display device according to one or more embodiments of the present disclosure.

In FIG. 3, a structure of a display panel DP is briefly shown based on a display area DA. However, according to one or more embodiments, at least one driving circuit unit (for example, at least one of a scan driver and a data driver), lines, and/or pads that are not shown may be further disposed on the display panel DP.

When a display device DD is an electronic device in which a display surface is applied to at least one surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, and/or a wearable device.

Referring to FIG. 3, the display panel DP may include a substrate SUB (or a base layer) and a pixel PXL provided on the substrate SUB.

The display panel DP may have various shapes. For example, the display panel DP may be provided in a rectangular plate shape, but is not limited thereto. For example, the display panel DP may have a shape of a circle, an ellipse, or the like. In addition, the display panel DP may include an angled corner and/or a curved corner. For convenience, in FIG. 3, the display panel DP is shown as having the rectangular plate shape. In addition, in FIG. 3, an extension direction of a short side of the display panel DP (for example, a horizontal direction) is denoted as a first direction DR1, and an extension direction of a long side (for example, a vertical direction) is denoted as a second direction DR2.

The substrate SUB may configure a base member of the display panel DP and may be a rigid or flexible substrate or film. For example, the substrate SUB may be a rigid substrate formed of glass or tempered glass, a flexible substrate (or a thin film) of a plastic or metal material, or at least one layer of insulating layer. A material and/or a physical property of the substrate SUB are/is not particularly limited.

The substrate SUB (and the display panel DP) may include a display area DA for displaying an image and a non-display area NDA excluding the display area DA along an edge or periphery of the display area DA. The display area DA may configure a screen on which the image is displayed, and when the non-display area NDA is positioned on at least one side of the display area DA, for example, the non-display area NDA may be around (e.g., may surround) the display area DA, but is not limited thereto.

The pixel PXL may be disposed in the display area DA on the substrate SUB. A non-display area NDA may be disposed around the display area DA. In the non-display area NDA, various lines, pads, and/or embedded circuit units connected to the pixels PXL of the display area DA may be disposed.

In describing embodiments of the present disclosure, “connection (or access)” may comprehensively mean physical and/or electrical connection (or access). In addition, this may comprehensively mean direct or indirect connection (or access) and integral or non-integral connection (or access).

The pixel PXL may include sub-pixels SPX1 to SPX3, and for example, the pixel PXL may include a first sub-pixel SPX1, a second sub-pixel SPX2, and a third sub-pixel SPX3.

Each of the sub-pixels SPX1 to SPX3 may emit light of a desired color (e.g., a predetermined color). According to one or more embodiments, the sub-pixels SPX1 to SPX3 may emit light of different colors. For example, the first sub-pixel SPX1 may emit light of a first color, the second sub-pixel SPX2 may emit light of a second color, and the third sub-pixel SPX3 may emit light of a third color. For example, the first sub-pixel SPX1 may be a red pixel emitting red light, the second sub-pixel SPX2 may be a green pixel emitting green light, and the third sub-pixel SPX3 may be a blue pixel emitting blue light, but the present disclosure is not limited thereto.

The first sub-pixel SPX1, the second sub-pixel SPX2, and the third sub-pixel SPX3 may include a light emitting element of a first color, a light emitting element of a second color, and a light emitting element of a third color as light sources to emit light of the first color, the second color, and the third color, respectively. In another embodiment, the first sub-pixel SPX1, the second sub-pixel SPX2, and the third sub-pixel SPX3 may include light emitting elements emitting light of the same color, and may include color conversion layers and/or color filters of different colors disposed on each light emitting element to emit light of the first color, the second color, and the third color, respectively. However, a color, a type, the number, and/or the like of the sub-pixels SPX1 to SPX3 configuring each pixel PXL are/is not particularly limited. That is, a color of light emitted from each pixel PXL may be variously changed.

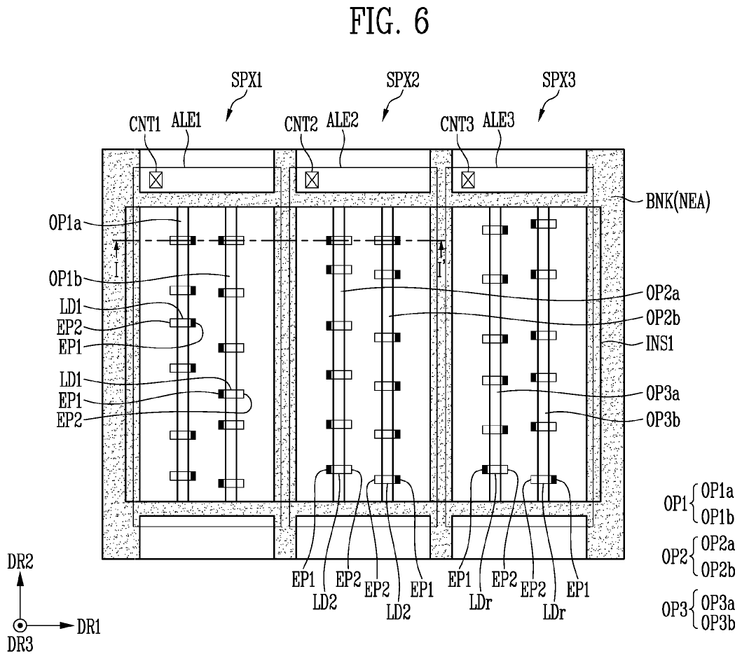

Hereinafter, the light emitting elements included in the first sub-pixel SPX1 may be referred to as first light emitting elements (for example, first light emitting element LD1 of FIG. 6). The light emitting elements included in the second sub-pixel SPX2 may be referred to as second light emitting elements (for example, second light emitting element LD2 of FIG. 6). The light emitting elements included in the third sub-pixel SPX3 may be referred to as third light emitting elements (for example, third light emitting element LD3 of FIG. 6).

The sub-pixels SPX1 to SPX3 may be regularly arranged according to a stripe or PENTILE® arrangement structure, but the present disclosure is not limited thereto. This PENTILE® arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. For example, the first, second, and third sub-pixels SPX1, SPX2, and SPX3 may be sequentially and repeatedly disposed along the first direction DR1 and may be repeatedly disposed along the second direction DR2. At least one of the first, second, and third sub-pixels SPX1, SPX2, and SPX3 disposed adjacent to each other may configure one pixel PXL capable of emitting light of various colors. However, an arrangement structure of the sub-pixels SPX1 to SPX3 is not limited thereto, and the sub-pixels SPX1 to SPX3 may be arranged in the display area DA in various structures and/or methods.

In one or more embodiments, each of the sub-pixels SPX1 to SPX3 may be configured as an active pixel. For example, each of the sub-pixels SPX1 to SPX3 may include at least one light source (for example, a light emitting element) driven by a suitable control signal (e.g., a predetermined control signal, for example, a scan signal and a data signal) and/or a suitable power (e.g., a predetermined power, for example, first power and second power). However, a type, a structure, and/or a driving method of the sub-pixels SPX1 to SPX3 applicable to the display device are/is not particularly limited.

Hereinafter, when collectively referring to the first sub-pixel SPX1, the second sub-pixel SPX2, and the third sub-pixel SPX3, the first sub-pixel SPX1, the second sub-pixel SPX2, and the third sub-pixel SPX3 are referred to as a sub-pixel SPX.

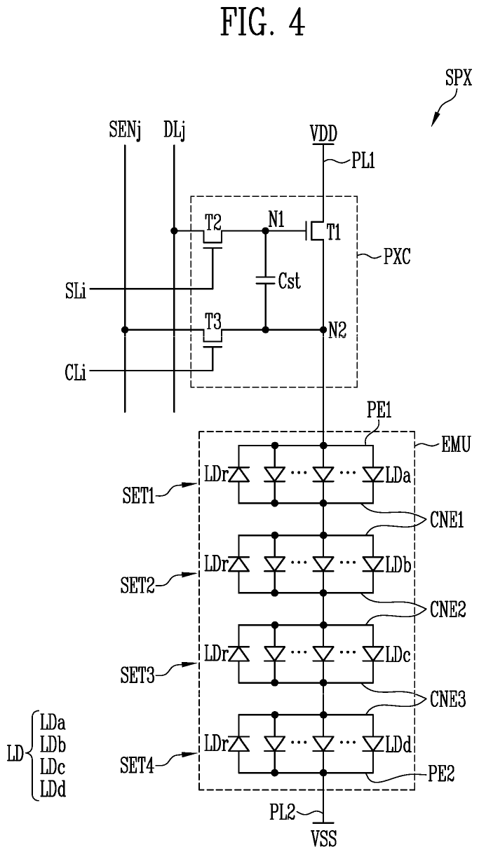

FIG. 4 is a circuit diagram illustrating an embodiment of the sub-pixel included in the display device of FIG. 3.

The sub-pixel SPX shown in FIG. 4 may be any one of the sub-pixels SPX1 to SPX3 shown in FIG. 3, and the sub-pixels SPX1 to SPX3 arranged in each display area DA may be configured substantially identical to or similar to each other.

For example, FIG. 4 shows an electrical connection relationship between components included in each sub-pixel SPX applicable to an active matrix display device according to one or more embodiments. However, a connection relationship between components of each sub-pixel SPX is not limited thereto.

The sub-pixel SPX may include a light emitting unit EMU (or a light emitting unit) that generates light of a luminance corresponding to the data signal. In addition, the sub-pixel SPX may selectively further include a pixel circuit PXC for driving the light emitting unit EMU.

According to one or more embodiments, the light emitting unit EMU may include a plurality of light emitting elements LD connected in parallel between a first power line PL1 and a second power line PL2. The first power line PL1 may be connected to first driving power VDD, and thus a voltage of the first driving power VDD may be applied to the first power line PL1. The second power line PL2 may be connected to second driving power VSS, and thus a voltage of the second driving power VSS may be applied to the second power line PL2.

For example, the light emitting unit EMU may include a first pixel electrode PE1 (or a first electrode) connected to the first driving power VDD through the pixel circuit PXC and the first power line PL1, a second pixel electrode PE2 (or a second electrode) connected to the second driving power VSS through the second power line PL2, and the plurality of light emitting elements LD connected in parallel in the same direction between the first pixel electrode PE1 and the second pixel electrode PE2. In one or more embodiments, the first pixel electrode PE1 may be an anode (or an anode electrode), and the second pixel electrode PE2 may be a cathode (or a cathode electrode).

Each of the light emitting elements LD included in the light emitting unit EMU may include a first end connected to the first driving power VDD through the first pixel electrode PE1 and a second end connected to the second driving power VSS through the second pixel electrode PE2. The first driving power VDD and the second driving power VSS may have different potentials. For example, the first driving power VDD may be set as high potential power, and the second driving power VSS may be set as low potential power. At this time, a potential difference between the first driving power VDD and the second driving power VSS may be set as a threshold voltage or more of the light emitting element LD during a light emission period of each sub-pixel SPX.

As described above, the respective light emitting elements LD connected in parallel in the same direction (for example, a forward direction) between the first pixel electrode PE1 and the second pixel electrode PE2 to which the voltages of the different power are supplied may configure respective effective light sources.

The light emitting elements LD of the light emitting unit EMU may emit light with a luminance corresponding to a driving current supplied through a corresponding pixel circuit PXC. For example, the pixel circuit PXC may supply a driving current corresponding to a grayscale value of corresponding frame data of the pixel circuit PXC to the light emitting unit EMU during each frame period. The driving current supplied to the light emitting unit EMU may be divided and may flow to each of the light emitting elements LD. Therefore, each of the light emitting elements LD may emit light with a luminance corresponding to the current flowing through the light emitting element LD, and thus the light emitting unit EMU may emit light of the luminance corresponding to the driving current.

In the above-described embodiment, an embodiment in which the both ends of the light emitting elements LD are connected in the same direction between the first and second driving power VDD and VSS is described, but the present disclosure is not limited thereto. According to one or more embodiments, the light emitting unit EMU may further include at least one ineffective light source, for example, a reverse light emitting element LDr, in addition to the light emitting elements LD configuring each effective light source. The reverse light emitting element LDr may be connected in parallel between the first and second pixel electrodes PE1 and PE2 together with the light emitting elements LD configuring the effective light sources, and may be connected between the first and second pixel electrodes PE1 and PE2 in a direction opposite to the light emitting elements LD.

The reverse light emitting element LDr maintains an inactivation state even though a predetermined driving voltage (for example, a driving voltage of a forward direction) is applied between the first and second pixel electrodes PE1 and PE2, and thus a current substantially does not flow through the reverse light emitting element LDr.

The pixel circuit PXC may be connected to a scan line SLi and a data line DLj of the sub-pixel SPX. In addition, the pixel circuit PXC may be connected to a control line CLi and a sensing line SENj of the sub-pixel SPX. For example, when the sub-pixel SPX is disposed in an i-th row and a j-th column of the display area DA, the pixel circuit PXC of the sub-pixel SPX may be connected to the i-th scan line SLi, the j-th data line DLj, the i-th control line CLi, and the j-th sensing line SENj of the display area DA. According to one or more embodiments, the control line CLi may be connected to the scan line SLi or may be the scan line SLi (e.g., may be an extension of the scan line SLi).

The pixel circuit PXC may include transistors T1 to T3 and a storage capacitor Cst (or a capacitor).

The first transistor T1 may be a driving transistor for controlling the driving current applied to the light emitting unit EMU, and may be connected between the first driving power VDD and the light emitting unit EMU. Specifically, a first terminal (or a first transistor electrode) of the first transistor T1 may be electrically connected to the first driving power VDD through the first power line PL1, a second terminal (or a second transistor electrode) of the first transistor T1 may be electrically connected to a second node N2, and a gate electrode of the first transistor T1 may be electrically connected to a first node N1. The first transistor T1 may control an amount of the driving current applied from the first driving power VDD to the light emitting unit EMU through the second node N2, according to a voltage applied to the first node N1. In one or more embodiments, the first terminal of the first transistor T1 may be a drain electrode, and the second terminal of the first transistor T1 may be a source electrode, but the present disclosure is not limited thereto. According to one or more embodiments, the first terminal may be a source electrode and the second terminal may be a drain electrode.

The second transistor T2 may be a switching transistor that selects the sub-pixel SPX in response to the scan signal and activates the sub-pixel SPX, and may be connected between the data line DLj and the first node N1. A first terminal of the second transistor T2 may be connected to the data line DLj, a second terminal of the second transistor T2 may be connected to the first node N1, and a gate electrode of the second transistor T2 may be connected to the scan line SLi. The first terminal and the second terminal of the second transistor T2 may be different terminals. For example, when the first terminal is a drain electrode, the second terminal may be a source electrode.

The second transistor T2 may be turned on when a scan signal of a gate-on voltage (for example, a high level voltage) is supplied from the scan line SLi, to electrically connect the data line DLj and the first node N1. The first node N1 may be a point where the second terminal of the second transistor T2 and the gate electrode of the first transistor T1 are connected, and the second transistor T2 may transmit the data signal to the gate electrode of the first transistor T1.

A first terminal of the third transistor T3 may be connected to the sensing line SENj, a second terminal of the third transistor T3 may be connected to the second terminal of the first transistor T1 at the second node N2, and a gate electrode of the third transistor T3 may be connected to the control line CLi. Initialization power (e.g., initialization voltage) may be applied to the sensing line SENj. The third transistor T3 may be an initialization transistor capable of initializing the second node N2, and may be turned on when a sensing control signal is supplied from the control line CLi to transmit a voltage of the initialization power to the second node N2. Accordingly, a second storage electrode of the storage capacitor Cst electrically connected to the second node N2 may be initialized. According to one or more embodiments, as the third transistor T3 may connect the first transistor T1 to the sensing line SENj, a sensing signal may be obtained through the sensing line SENj, and a characteristic of the sub-pixel SPX including a threshold voltage or the like of the first transistor T1 may be detected using the sensing signal. Information on the characteristic of the sub-pixel SPX may be used to convert image data so that a characteristic deviation between the sub-pixels SPX may be compensated.

The storage capacitor Cst may be formed between the first node N1 and the second node N2 or electrically connected between the first node N1 and the second node N2. The storage capacitor Cst charges a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

The light emitting unit EMU may be configured to include at least one series stage (or a stage) including the light emitting elements LD electrically connected to each other in parallel.

In one or more embodiments, the light emitting unit EMU may also be configured in a series/parallel mixed structure. For example, as shown in FIG. 4, the light emitting unit EMU may also be configured to include a first series stage SET1, a second series stage SET2, a third series stage SET3, and a fourth series stage SET4. The number of series stages included in the light emitting unit EMU may be variously changed, and for example, the light emitting unit EMU may include one, two, three, or five or more series stages.

The light emitting unit EMU may include the first series stage SET1, the second series stage SET2, the third series stage SET3, and the fourth series stage SET4 sequentially connected between the first driving power VDD and the second driving power VSS.

The first series stage SET1 (or a first stage) may include the first pixel electrode PE1 and a first connection electrode CNE1, and may include at least one (1-1)-th light emitting element LDa connected between the first pixel electrode PE1 and the first connection electrode CNE1. In addition, the first series stage SET1 may further include a reverse light emitting element LDr connected in a direction opposite to the (1-1)-th light emitting element LDa between the first pixel electrode PE1 and the first connection electrode CNE1.

The second series stage SET2 (or a second stage) may include the first connection electrode CNE1 and a second connection electrode CNE2, and may include at least one (1-2)-th light emitting element LDb connected between the first connection electrode CNE1 and the second connection electrode CNE2. In addition, the second series stage SET2 may further include a reverse light emitting element LDr connected in a direction opposite to the (1-2)-th light emitting element LDb between the first connection electrode CNE1 and the second connection electrode CNE2.

The third series stage SET3 (or a third stage) may include the second connection electrode CNE2 and a third connection electrode CNE3, and may include at least one (1-3)-th light emitting element LDc connected between the second connection electrode CNE2 and the third connection electrode CNE3. In addition, the third series stage SET3 may further include a reverse light emitting element LDr connected in a direction opposite to the (1-3)-th light emitting element LDc between the second connection electrodes CNE2 and the third connection electrode CNE3.

The fourth series stage SET4 (or a fourth stage) may include the third connection electrode CNE3 and the second pixel electrode PE2, and may include at least one (1-4)-th light emitting element LDd connected between the third connection electrode CNE3 and the second pixel electrode PE2. In addition, the third series stage SET3 may further include a reverse light emitting element LDr connected in a direction opposite to the (1-4)-th light emitting element LDd between the third connection electrode CNE3 and the second pixel electrode PE2.

As described above, the light emitting unit EMU of the sub-pixel SPX including the series stages SET1 to SET4 (or the light emitting elements LD) connected in the series/parallel mixed structure may easily control a driving current and/or voltage condition according to a specification or a requirement of a product to which it is applied.

In particular, the light emitting unit EMU of the sub-pixel SPX including the series stages SET1 to SET4 may reduce the driving current compared to a light emitting unit of a structure in which the light emitting elements LD are connected only in parallel. In other words, the light emitting unit EMU of the sub-pixel SPX including the series stages SET1 to SET4 may emit light with a higher luminance with respect to the same driving current.

In addition, the light emitting unit EMU of the sub-pixel SPX including the series stages SET1 to SET4 may reduce the driving voltage applied to both ends of the light emitting unit EMU compared to a light emitting unit of a structure in which the same number of all light emitting elements LD are connected in series.

In FIG. 4, all transistors T1 to T3 included in the pixel circuit PXC are n-type transistors, but are not necessarily limited thereto. For example, at least one of the transistors T1 to T3 may be changed to a p-type transistor.

In addition, a structure and a driving method of the sub-pixel SPX may be variously changed. For example, the pixel circuit PXC may be configured of a pixel circuit of various structures and/or driving methods, in addition to the embodiment shown in FIG. 4.

For example, the pixel circuit PXC may not include the third transistor T3. In addition, the pixel circuit PXC may further include other circuit elements such as a compensation transistor for compensating for the threshold voltage or the like of the first transistor T1, an initialization transistor for initializing a voltage of the first node N1 and/or the first pixel electrode PE1, an emission control transistor for controlling a period in which the driving current is supplied to the light emitting unit EMU, a boosting capacitor for boosting the voltage of the first node N1, and/or the like.

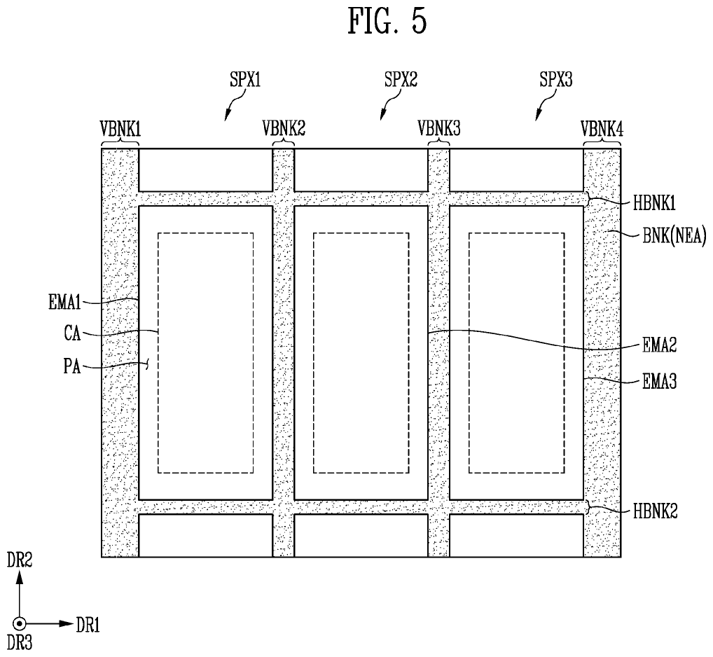

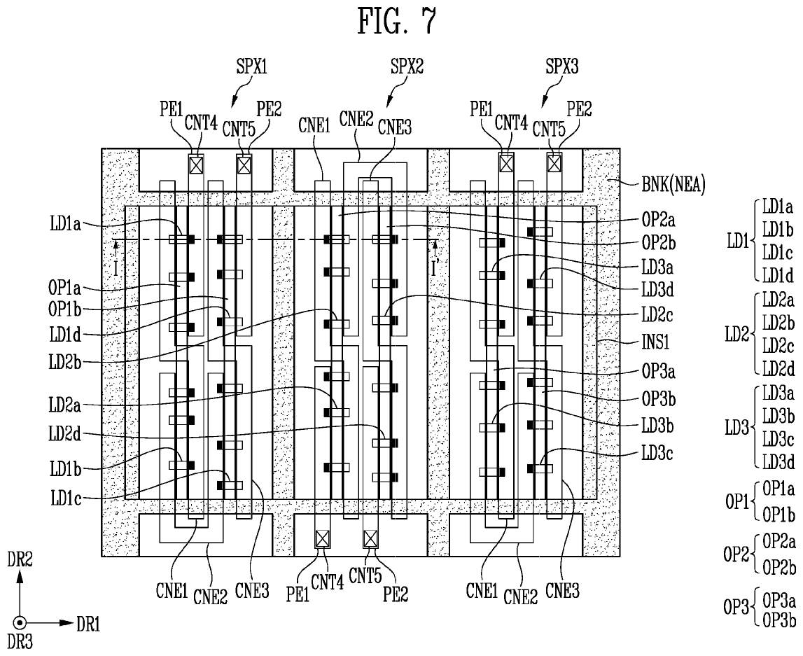

FIG. 5 is a schematic plan view illustrating an embodiment of a bank partitioning the sub-pixels included in the display device of FIG. 3. FIG. 6 is a schematic plan view illustrating an embodiment of the sub-pixels included in the display device of FIG. 3. FIG. 7 is a schematic plan view illustrating an embodiment of the sub-pixels included in the display device of FIG. 3.

FIG. 5 is a diagram illustrating emission areas EMA1, EMA2, and EMA3 and a non-emission area NEA of the first, second, and third sub-pixels SPX1, SPX2, and SPX3, and FIG. 5 is shown based on the bank BNK. FIGS. 6 and 7 are diagram illustrating some configurations included in the first, second, and third sub-pixels SPX1, SPX2, and SPX3 based on the bank BNK of FIG. 5. FIG. 6 is a diagram illustrating light emitting elements LD1, LD2, and LD3, alignment electrodes ALE1 to ALE3, and a first insulating layer INS1. FIG. 7 is a diagram illustrating the light emitting elements LD1, LD2, and LD3, the pixel electrodes PE1 and PE2, and the connection electrodes CNE1, CNE2, and CNE3.

Referring to FIGS. 3 to 7, the display device DD may include the bank BNK, the alignment electrodes ALE1, ALE2, and ALE3, the first insulating layer INS1, the light emitting elements LD1, LD2, and LD3, the pixel electrodes PE1 and PE2, and the connection electrodes CNE1, CNE2, and CNE3 to configure the sub-pixels SPX1, SPX2, and SPX3.

As shown in FIG. 5, the bank BNK may partition the first sub-pixel SPX1, the second sub-pixel SPX2, and the third sub-pixel SPX3. The first sub-pixel SPX1 may include a first emission area EMA1, the second sub-pixel SPX2 may include a second emission area EMA2, and the third sub-pixel SPX3 may include a third emission area EMA3.

In one or more embodiments, the first emission area EMA1, the second emission area EMA2, and the third emission area EMA3 may correspond to an opening defined by the bank BNK.

In one or more embodiments, the bank BNK may form a space in which fluid may be accommodated. For example, during a manufacturing process, an ink including the light emitting elements LD1, LD2, and LD3 may be provided in the space.

In one or more embodiments, the non-emission area NEA may be an area substantially corresponding to the bank BNK. The bank BNK may surround each of the first emission area EMA1, the second emission area EMA2, and the third emission area EMA3, in a plan view.

In one or more embodiments, the bank BNK may include a first horizontal extension portion HBNK1 and a second horizontal extension portion HBNK2 extending in the first direction DR1 in correspondence with the vertical direction. The first horizontal extension portion HBNK1 and the second horizontal extension portion HBNK2 may be spaced from each other in the second direction DR2 (for example, the vertical direction).

In one or more embodiments, the bank BNK may include a first vertical extension portion VBNK1, a second vertical extension portion VBNK2, a third vertical extension portion VBNK3, and a fourth vertical extension portion VBNK4 extending in the second direction DR2. In an example, the first vertical extension portion VBNK1, the second vertical extension portion VBNK2, the third vertical extension VBNK3 portion, and the fourth vertical extension portion VBNK4 may be spaced in the first direction DR1.

In one or more embodiments, the first emission area EMA1 partitioned by the first vertical extension portion VBNK1, the second vertical extension portion VBNK2, the first horizontal extension portion HBNK1, and the second horizontal extension portion HBNK2 may be formed (e.g., defined). Similarly, the second emission area EMA2 partitioned by the second vertical extension portion VBNK2, the third vertical extension portion VBNK3, the first horizontal extension portion HBNK1, and the second horizontal extension portion HBNK2 may be formed (e.g., defined). The third emission area EMA3 partitioned by the third vertical extension portion VBNK3, the fourth vertical extension portion VBNK4, the first horizontal extension portion HBNK1, and the second horizontal extension portion HBNK2 may be formed (e.g., defined). Therefore, the first emission area EMA1, the second emission area EMA2, and the third emission area EMA3 may be sequentially arranged along the first direction DR1.

In one or more embodiments, the first emission area EMA1 may be adjacently disposed with the second emission area EMA2 and the second vertical extension portion VBNK2 interposed therebetween. The second emission area EMA2 may be adjacently disposed with the third emission area EMA3 and the third vertical extension portion VBNK3 interposed therebetween.

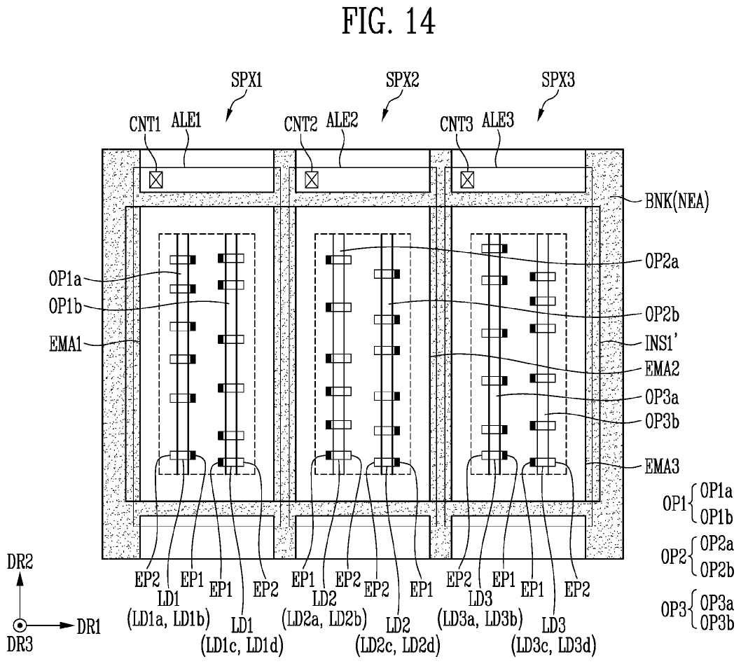

In one or more embodiments, each of the first to third emission areas EMA1 to EMA3 may include a central area CA and a peripheral area PA. The center area CA may be an area defined by being spaced from the bank BNK by a suitable distance (e.g., a predetermined distance, for example, a first distance). The peripheral area PA may be an area surrounding the central area CA. In an example, a density of light emitting elements (for example, the light emitting elements LD of FIG. 1) in the central area CA may be higher than a density of light emitting elements in the peripheral area PA, but is not limited thereto. The density of the light emitting element is described later with reference to FIG. 14.

Referring to FIG. 6, the first sub-pixel SPX1 may include a first alignment electrode ALE1. The second sub-pixel SPX2 may include a second alignment electrode ALE2. The third sub-pixel SPX3 may include a third alignment electrode ALE3.

The first, second, and third alignment electrodes ALE1, ALE2, and ALE3 may be sequentially arranged to be apart from each other in the first direction DR1 and may extend in the second direction DR2. The first, second, and third alignment electrodes ALE1, ALE2, and ALE3 may be disposed under the bank BNK.

The first alignment electrode ALE1 may cover the first emission area EMA1. The second alignment electrode ALE2 may cover the second emission area EMA2. The third alignment electrode ALE3 may cover the third emission area EMA3.

Referring to FIGS. 5 and 6, the first alignment electrode ALE1 may overlap the first vertical extension portion VBNK1, the first emission area EMA1, and the second vertical extension portion VBNK2. The second alignment electrode ALE2 may overlap the second vertical extension portion VBNK2, the second emission area EMA2, and the third vertical extension portion VBNK3. The third alignment electrode ALE3 may overlap the third vertical extension portion VBNK3, the third emission area EMA3, and the fourth vertical extension portion VBNK4.

In one or more embodiments, a boundary area between the first alignment electrode ALE1 and the second alignment electrode ALE2 may overlap one area (for example, the second vertical extension portion VBNK2) of the bank BNK. A boundary area between the second alignment electrode ALE2 and the third alignment electrode ALE3 may overlap one area (for example, the third vertical extension portion VBNK3) of the bank BNK.

In one or more embodiments, the first light emitting element LD1 may be disposed on the first alignment electrode ALE1. The second light emitting element LD2 may be disposed on the second alignment electrode ALE2. The third light emitting element LD3 may be disposed on the third alignment electrode ALE3.

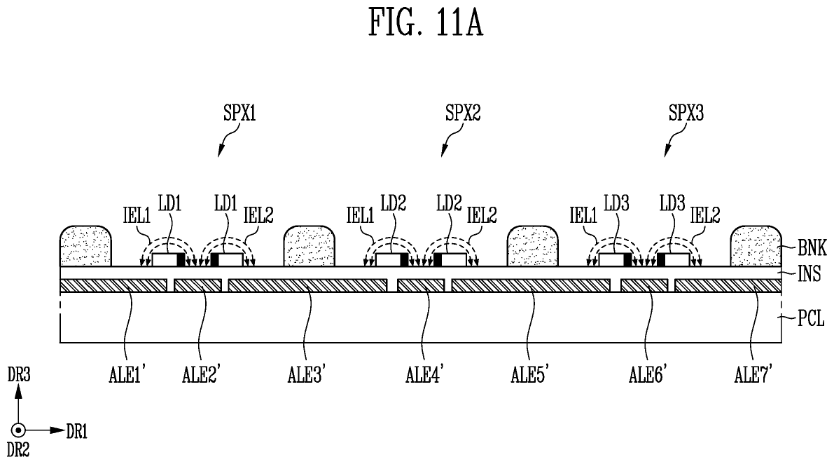

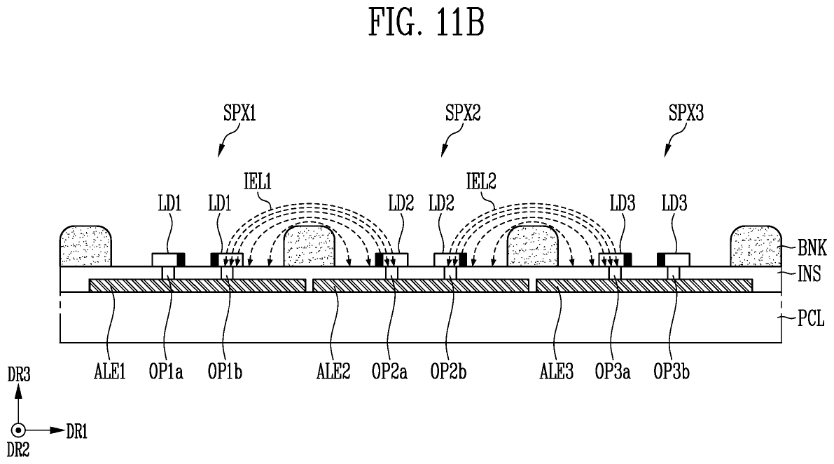

In one or more embodiments, the first, second, and third alignment electrodes ALE1, ALE2, and ALE3 may be electrodes for aligning the light emitting elements LD1, LD2, and LD3. In a process of manufacturing the display device, when a voltage is applied to an alignment electrode, a first electric field (for example, a first electric field IEL1 of FIG. 11B) may be formed between (or on) the first alignment electrode ALE1 and the second alignment electrode ALE2. A portion of the first light emitting element LD1 may be disposed on the first alignment electrode ALE1 based on the first electric field IEL1, and a portion of the second light emitting element LD2 may be disposed on the second alignment electrode ALE2 based on the first electric field IEL1. This is described later with reference to FIG. 11B.

A second electric field (for example, a second electric field IEL2 of FIG. 11B) may be formed between (or on) the second alignment electrode ALE2 and the third alignment electrode ALE3. A rest of the second light emitting element LD2 may be disposed on the second alignment electrode ALE2 based on the second electric field IEL2, and a portion of the third light emitting element LD3 may be disposed on the third alignment electrode ALE3 based on the second electric field IEL2.

When the first sub-pixel SPX1 is a sub-pixel adjacent to an edge of the display device DD (for example, the non-display area NDA of FIG. 3), a dummy alignment electrode may be disposed to overlap one area of the bank BNK adjacent to the non-emission area NEA. In a process of aligning the first light emitting element LD1, a rest of the first light emitting element LD1 may be disposed on the first alignment electrode ALE1 by an electric field formed as a control signal is applied to the dummy electrode and the first alignment electrode ALE1.

In one or more embodiments, each of the first to third alignment electrodes ALE1, ALE2, and ALE3 may be supplied (or provided) with a first alignment signal or a second alignment signal in a process step in which the first, second, and third light emitting elements LD1, LD2, and LD3 are aligned (hereinafter, an alignment process).

In one or more embodiments, the first alignment signal and the second alignment signal may have different waveforms, potentials, and/or phases. The first alignment signal may be a ground signal, and the second alignment signal may be an AC signal. However, the present disclosure is not limited to the above-described example. For example, the first alignment signal may be an AC signal, and the second alignment signal may be a ground signal.

In one or more embodiments, the first alignment signal may be applied to the first alignment electrode ALE1 and the third alignment electrode ALE3. The second alignment signal may be applied to the second alignment electrode ALE2 disposed between the first alignment electrode ALE1 and the third alignment electrode ALE3.

In one or more embodiments, the first alignment electrode ALE1 may be connected to a lower first signal line through a first contact hole CNT1, and in the alignment process, the first alignment signal may be provided to the first alignment electrode ALE1 through a first signal line.

In one or more embodiments, the second alignment electrode ALE2 may be connected to a lower second signal line through a second contact hole CNT2, and in the alignment process, the second alignment signal may be provided to the second alignment electrode ALE2 through a second signal line.

In one or more embodiments, the third alignment electrode ALE3 may be connected to the lower first signal line through a third contact hole CNT3, and in the alignment process, the first alignment signal may be provided to the third alignment electrode ALE3 through the first signal line.

In one or more embodiments, the first alignment electrode ALE1 may have substantially the same planar shape as the third alignment electrode ALE3, and the same alignment signal may be supplied to the first alignment electrode ALE1 and the third alignment electrode ALE3.

In one or more embodiments, each of the first to third contact holes CNT1 to CNT3 may be disposed in one area of the first to third alignment electrodes ALE1, ALE2, and ALE3 corresponding to an area that does not overlap the bank BNK in a plan view.

In one or more embodiments, shapes of each of the first to third alignment electrodes ALE1 to ALE3 may be the same, but are not limited thereto, and the shapes of the first to third alignment electrodes ALE1 to ALE3 may be different. For example, the first and third alignment electrodes ALE1 and ALE3 may have a curved shape, and the second alignment electrode ALE2 may have a bar shape.

Cross-sectional areas of the first to third alignment electrodes ALE1 to ALE3 may be the same as each other, but are not limited thereto.

The respective first to third alignment electrodes ALE1 to ALE3 may be disposed to cover the first to third emission areas EMA1 to EMA3, and may shield a parasitic electric field occurring due to elements included in the pixel circuit (for example, the pixel circuit PXC of FIG. 4) disposed under (for example, a third direction DR3) the first to third alignment electrodes ALE1 to ALE3. That is, in an alignment process of the first to third light emitting elements LD1 to LD3, distortion of the first electric field formed between the first alignment electrode ALE1 and the second alignment electrode ALE2 and the second electric field formed between the second alignment electrode ALE2 and the third alignment electrode ALE3 due to the parasitic electric field may be prevented. Therefore, the first to third light emitting elements LD1 to LD3 may be normally disposed on the first to third alignment electrodes ALE1 to ALE3.

In one or more embodiments, the first insulating layer INS1 may be disposed to overlap the first to third emission areas EMA1 to EMA3.

In FIG. 6, the first insulating layer INS1 is partially disposed on the base (or the base layer) to overlap the first to fourth vertical extension portions VBNK1 to VBNK4 and the first to third emission areas EMA1, EMA2, and EMA3, but the first insulating layer INS1 may be entirely disposed on the substrate to overlap the bank BNK and the first to third alignment electrodes ALE1 to ALE3.

In one or more embodiments, the first insulating layer INS1 may include first to third openings OP1 to OP3. The first opening OP1 may overlap the first emission area EMA1. The second opening OP2 may overlap the second emission area EMA2. The third opening OP3 may overlap the third emission area EMA3.

The respective first to third light emitting elements LD1, LD2, and LD3 may be disposed in the first to third openings OP1 to OP3. In an example, the first light emitting element LD1 may be disposed in an area corresponding to the first opening OP1. The second light emitting element LD2 may be disposed in an area corresponding to the second opening OP2. The third light emitting element LD3 may be disposed in an area corresponding to the third opening OP3.

The first opening OP1 may include a (1-1)-th opening OP1a and a (1-2)-th opening OP1b. The (1-1)-th opening OP1a and the (1-2)-th opening OP1b may be disposed to be spaced from each other in the first direction DR1. Each of the (1-1)-th opening OP1a and (1-2)-th opening OP1b may be one opening extending in the second direction DR2. The (1-2)-th opening OP1b may be disposed closer to the second alignment electrode ALE2 than the (1-1)-th opening OP1a. The (1-1)-th opening OP1a may be disposed closer to the third alignment electrode ALE3 included in a pixel adjacent to the corresponding pixel PLX than the (1-2)-th opening OP1b.

The second opening OP2 may include a (2-1)-th opening OP2a and a (2-2)-th opening OP2b. The (2-1)-th opening OP2a and the (2-2)-th opening OP2b may be disposed to be spaced from each other in the first direction DR1. Each of the (2-1)-th opening OP2a and the (2-2)-th opening OP2b may be one opening extending in the second direction DR2. The (2-1)-th opening OP2a may be disposed closer to the first alignment electrode ALE1 than the (2-2)-th opening OP2b. The (2-2)-th opening OP2b may be disposed closer to the third alignment electrode ALE3 than the (2-1)-th opening OP2a.

The third opening OP3 may include a (3-1)-th opening OP3a and a (3-2)-th opening OP3b. The (3-1)-th opening OP3a and the (3-2)-th opening OP3b may be disposed to be spaced from each other in the first direction DR1. Each of the (3-1)-th opening OP3a and the (3-2)-th opening OP3b may be one opening extending in the second direction DR2. The (3-1)-th opening OP3a may be disposed closer to the second alignment electrode ALE2 than the (3-2)-th opening OP3a. The (3-2)-th opening OP3b may be disposed adjacent to the first alignment electrode ALE1 included in a pixel adjacent to the pixel PLX than the (3-1)-th opening OP3a.

During a manufacturing process of the display device, when an alignment voltage is applied to the first to third alignment electrodes ALE1 to ALE3, an electric field may be concentrated to the first to third openings OP1 to OP3 of the first insulating layer INS1.

In one or more embodiments, an alignment signal may be supplied to the first to third alignment electrodes ALE1, ALE2, and ALE3 in the alignment process.

When the first electric field is formed between the first alignment electrode ALE1 and the second alignment electrode ALE2, the first electric field may be concentrated through the (1-2)-th opening OP1b and the (2-1)-th opening OP2a.

A portion of the first light emitting element LD1 disposed on the first alignment electrode ALE1 may move to the (1-2)-th opening OP1b where the first electric field is concentrated by force (for example, dielectrophoresis (DEP) force) according to the first electric field. The portion of the first light emitting element LD1 may be disposed on the (1-2)-th opening OP1b.

A portion of the second light emitting element LD2 disposed on the second alignment electrode ALE2 may move to the (2-1)-th opening OP2a where the first electric field is concentrated by force according to the first electric field. The portion of the second light emitting element LD2 may be disposed on the (2-1)-th opening OP2a.

The first light emitting element LD1 disposed on the (1-2)-th opening OP1b and the second light emitting element LD2 disposed on the (2-1)-th opening OP2a may be disposed in the same direction. In an example, in a plan view, the second end EP2 of the first light emitting element LD1 disposed on the (1-2)-th opening OP1b may be disposed to face the first end EP1 of the second light emitting element LD2 disposed on the (2-1)-th opening OP2a.

When the second electric field is formed between the second alignment electrode ALE2 and the third alignment electrode ALE3, the second electric field may be concentrated through the (2-2)-th opening OP2b and the (3-1)-th opening OP3a.

A portion of the second light emitting element LD2 disposed on the second alignment electrode ALE2 may move to the (2-2)-th opening OP2b where the second electric field is concentrated by a force according to the second electric field. The portion of the second light emitting element LD2 may be disposed on the (2-2)-th opening OP2b.

A portion of the third light emitting element LD3 disposed on the third alignment electrode ALE3 may move to the (3-1)-th opening OP3a where the second electric field is concentrated by a force according to the second electric field. The portion of the third light emitting element LD3 may be disposed on the (3-1)-th opening OP3a.

The second light emitting element LD2 disposed on the (2-2)-th opening OP2b and the third light emitting element LD3 disposed on the (3-1)-th opening

OP3a may be disposed in the same direction. In an example, in a plan view, the first end EP1 of the second light emitting element LD2 disposed on the (2-2)-th opening OP2b may be disposed to face the second end EP2 of the third light emitting element LD3 disposed on the (3-1)-th opening OP3a.

The first electric field and the second electric field formed between the first to third alignment electrodes ALE1 to ALE3 may be concentrated to the first to third openings OP1 to OP3 included in the first insulating layer INS1. Therefore, in the alignment process of the first to third light emitting elements LD1 to LD3, the respective first to third light emitting elements LD1 to LD3 may be aligned along the first to third openings OP1 to OP3. Because the respective first to third light emitting elements LD1 to LD3 are uniformly aligned along the first to third openings OP1 to OP3, reliability of the display device may be secured.

Referring to FIGS. 3 and 7, each of the first sub-pixel SPX1, the second sub-pixel SPX2, and the third sub-pixel SPX3 may include the first pixel electrode PE1, the second pixel electrode PE2, and the connection electrodes CNE1 to CNE3. Because the first to third sub-pixels SPX1 to SPX3 are the same, the first sub-pixel SPX1 is mainly described.

In one or more embodiments, the first sub-pixel SPX1 may include the first light emitting element LD1. The first light emitting element LD1 may include a (1-1)-th light emitting element LD1a, a (1-2)-th light emitting element LD1b, a (1-3)-th light emitting element LD1c, and a (1-4)-th light emitting element LD1d. The (1-1)-th light emitting element LD1a and the (1-2)-th light emitting element LD1b may be disposed on the (1-1)-th opening OP1a. The (1-3)-th light emitting element LD1c and (1-4)-th light emitting element LD1d may be disposed on the (1-2)-th opening OP1b. In one or more embodiments, the second sub-pixel SPX2 may include the second light emitting element LD2. The second light emitting element LD2 may include a (2-1)-th light emitting element LD2a, a (2-2)-th light emitting element LD2b, a (2-3)-th light emitting element LD2c, and a (2-4)-th light emitting element LD2d. The (2-1)-th light emitting element LD2a and the (2-2)-th light emitting element LD2b may be disposed on the (2-1)-th opening OP2a. The (2-3)-th light emitting element LD2c and the (2-4)-th light emitting element LD2d may be disposed on the (2-2)-th opening OP2b.

In one or more embodiments, the third sub-pixel SPX3 may include the third light emitting element LD3. The third light emitting element LD3 may include a (3-1)-th light emitting element LD3a, a (3-2)-th light emitting element LD3b, a (3-3)-th light emitting element LD3c, and a (3-4)-th light emitting element LD3d. The (3-1)-th light emitting element LD3a and the (3-2)-th light emitting element LD3b may be disposed on the (3-1)-th opening OP3a. The (3-3)-th light emitting element LD3c and the (3-4)-th light emitting element LD3d may be disposed on the (3-2)-th opening OP3b.

In one or more embodiments, the first and second pixel electrodes PE1 and PE2 and the connection electrodes CNE1 to CNE3 may be provided in each of the first to third emission areas EMA1 to EMA3.

Referring to FIGS. 6 and 7, in a case of the first sub-pixel SPX1, the first pixel electrode PE1, the second pixel electrode PE2, and the connection electrodes CNE1 to CNE3 may be disposed on the first alignment electrode ALE1, the first insulating layer INS1, and the first light emitting element LD1 to be electrically connected to the first light emitting element LD1.

In a case of the second sub-pixel SPX2, the first pixel electrode PE1, the second pixel electrode PE2, and the connection electrodes CNE1 to CNE3 may be disposed on the second alignment electrode ALE2, the first insulating layer INS1, and the second light emitting element LD2 to be electrically connected to the second light emitting element LD2.

In a case of the third sub-pixel SPX3, the first pixel electrode PE1, the second pixel electrode PE2, and the connection electrodes CNE1 to CNE3 may be disposed on the third alignment electrode ALE3, the first insulating layer INS1, and the third light emitting element LD3 to be electrically connected to the third light emitting element LD3.

In one or more embodiments, the first pixel electrode PE1 may be disposed on the first end EP1 of the (1-1)-th light emitting element LD1a to be electrically connected to the first end EP1 of the (1-1)-th light emitting element LD1a.

The first connection electrode CNE1 may be disposed on the second end EP2 of the (1-1)-th light emitting element LD1a to be electrically connected to the second end EP2 of the (1-1)-th light emitting element LD1a. In addition, the first connection electrode CNE1 may be disposed on the first end EP1 of the (1-2)-th light emitting element LD1b to be electrically connected to the first end EP1 of the (1-2)-th light emitting element LD1b. In an example, the first connection electrode CNE1 may electrically connect the second end EP2 of the (1-1)-th light emitting element LD1a and the first end EP1 of the (1-2)-th light emitting element LD1b. To this end, the first connection electrode CNE1 may have a curved shape. For example, the first connection electrode CNE1 may have a bent or curved structure at a boundary between an area where the (1-1)-th light emitting element LD1a is arranged and an area where the (1-2)-th light emitting element LD1b is arranged.

The second connection electrode CNE2 may be disposed on the second end EP2 of the (1-2)-th light emitting element LD1b to be electrically connected to the second end EP2 of the (1-2)-th light emitting element LD1b. In addition, the second connection electrode CNE2 may be disposed on the first end EP1 of the (1-3)-th light emitting element LD1c to be electrically connected to the first end EP1 of the (1-3)-th light emitting element LD1c. In an example, the second connection electrode CNE2 may electrically connect the second end EP2 of the (1-2)-th light emitting element LD1b and the first end EP1 of the (1-3)-th light emitting element LD1c. To this end, the second connection electrode CNE2 may have a curved shape. For example, the second connection electrode CNE2 may have a bent or curved structure at a boundary between an area where the (1-2)-th light emitting element LD1b is arranged and an area where the (1-3)-th light emitting element LD1c is arranged.

The third connection electrode CNE3 may be disposed on the second end EP2 of the (1-3)-th light emitting elements LD1c to be electrically connected to the second end EP2 of the (1-3)-th light emitting elements LD1c. In addition, the third connection electrode CNE3 may be disposed on the first end EP1 of the (1-4)-th light emitting element LD1d to be electrically connected to the first end EP1 of the (1-4)-th light emitting element LD1d. In an example, the third connection electrode CNE3 may electrically connect the second end EP2 of the (1-3)-th light emitting elements LD1c and the first end EP1 of the (1-4)-th light emitting elements LD1d. To this end, the third connection electrode CNE3 may have a curved shape. For example, the third connection electrode CNE3 may have a bent or curved structure at a boundary between an area where the (1-3)-th light emitting element LD1c is arranged and an area where the (1-4)-th light emitting element LD1d is arranged.

In one or more embodiments, the second pixel electrode PE2 may be disposed on another area (for example, an upper end area) of the first alignment electrode ALE1 and the second end EP2 of the (1-4)-th light emitting elements LD1d to be electrically connected to the second end EP2 of the (1-4)-th light emitting elements LD1d.

The first and second pixel electrodes PE1 and PE2 and the connection electrodes CNE1 to CNE3 disposed on the third sub-pixel SPX3 may be disposed identically to the first and second pixel electrodes PE1 and PE2 and the connection electrodes CNE1 to CNE3 disposed on the first sub-pixel SPX1. The first and second pixel electrodes PE1 and PE2 and the connection electrodes CNE1 to CNE3 disposed on the second sub-pixel SPX2 may have a structure disposed to be symmetrical to an origin with respect to the first and second pixel electrodes PE1 and PE2 and the connection electrodes CNE1 to CNE3 disposed in the first sub-pixel SPX1.

In the above-described method, the (1-1)-th to (1-4)-th light emitting elements may be connected in a desired form on the first insulating layer INS1 using the first and second pixel electrodes PE1 and PE2 and the connection electrodes CNE1 to CNE3. For example, the (1-1)-th to (1-4)-th light emitting elements LD1a to LD1d may be sequentially connected in series using the pixel electrodes PE1 and PE2 and the connection electrodes CNE1 to CNE3.

In one or more embodiments, the first pixel electrode PE1 may be electrically connected to the first power line (for example, the first power line PL1 of FIG. 4) through a fourth contact hole CNT4 to be connected to the first driving power. The second pixel electrode PE2 may be electrically connected to the second power line (for example, the second power line PL2 of FIG. 4) through a fifth contact hole CNT5 to be connected to the second driving power.

In one or more embodiments, each of the fourth and fifth contact holes CNT4 and CNT5 may be disposed in one area of the first and second pixel electrodes PE1 and PE2 corresponding to an area which does not overlap the bank BNK in a plan view.

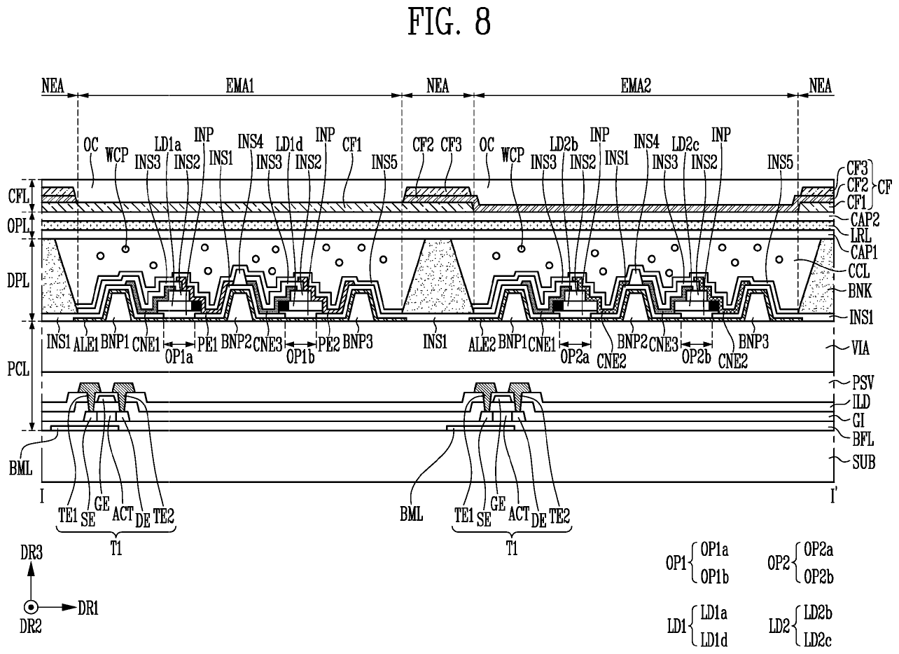

FIG. 8 is a schematic cross-sectional view illustrating an embodiment taken along the line I-I′ of FIGS. 6 and 7.

Referring to FIG. 8, the first and second sub-pixels SPX1 and SPX2 may include the substrate SUB, a pixel circuit layer PCL, a display element layer DPL, an optical layer OPL, and a color filter layer CFL.

In one or more embodiments, the substrate SUB may form a base member of the display device DD (refer to FIG. 3). The substrate SUB may be a rigid or flexible substrate or film. The substrate SUB may include a transparent insulating material, and thus may transmit light.

In one or more embodiments, the substrate SUB may be a rigid substrate. For example, the rigid substrate may be one of a glass substrate, a quartz substrate, a glass ceramic substrate, and/or a crystalline glass substrate. In an example, the substrate SUB may be a flexible substrate. Here, the flexible substrate may be one of a film substrate and a plastic substrate including a polymeric organic material. However, a material configuring the substrate SUB may be variously changed, and may include fiber reinforced plastic (FRP) or the like.

In one or more embodiments, the pixel circuit layer PCL may be disposed on the substrate SUB.

As shown in FIG. 8, the pixel circuit layer PCL may include a lower auxiliary electrode BML, a buffer layer BFL, the first transistor T1, a gate insulating layer GI, an interlayer insulating layer ILD, a protective layer PSV, and a via layer VIA. In FIG. 8, only the first transistor T1 from among circuit elements is shown for convenience of description.

In one or more embodiments, the lower auxiliary electrode BML may be disposed on the substrate SUB. The auxiliary lower electrode BML may function as a path through which an electrical signal moves. According to one or more embodiments, a portion of the lower auxiliary electrode BML may overlap the first transistor T1 in a plan view.

In one or more embodiments, the buffer layer BFL may be disposed on the substrate SUB. The buffer layer BFL may cover the lower auxiliary electrode BML. The buffer layer BFL may prevent an impurity from diffusing from an outside. The buffer layer BFL may include one of silicon oxide (SiOₓ), silicon nitride (SiNₓ), silicon oxynitride (SiOₓN_{y}), aluminum oxide (AlOₓ), and/or titanium oxide (TiOₓ).

In one or more embodiments, the first transistor T1 may be electrically connected to the light emitting elements LD1a and LD1d of the first sub-pixel SPX1 and the light emitting elements LD2b and LD2c of the second sub-pixel SPX2. The first transistor T1 may include an active layer ACT, a first transistor electrode TE1, a second transistor electrode TE2, and a gate electrode GE.

In one or more embodiments, the active layer ACT may mean a semiconductor layer. The active layer ACT may be disposed on the buffer layer BFL. The active layer ACT may include one of polysilicon, low temperature polycrystalline silicon (LTPS), amorphous silicon, and/or an oxide semiconductor.

In one or more embodiments, the active layer ACT may include a first contact area contacting the first transistor electrode TE1 and a second contact area contacting the second transistor electrode TE2. The first contact area and the second contact area may be a semiconductor pattern doped with an impurity. An area between the first contact area and the second contact area may be a channel area. The channel area may be an intrinsic semiconductor pattern that is not doped with an impurity.

In one or more embodiments, the gate insulating layer GI may be disposed on the active layer ACT. The gate insulating layer GI may include one of silicon oxide (SiOₓ), silicon nitride (SiNₓ), silicon oxynitride (SiOₓN_{y}), aluminum oxide (AlOₓ), and/or titanium oxide (TiOₓ).

In one or more embodiments, the gate electrode GE may be disposed on the gate insulating layer GI. The gate electrode GE may correspond to a position of the channel area of the active layer ACT. For example, the gate electrode GE may be disposed on the channel area of the active layer ACT with the gate insulating layer GI interposed therebetween.

In one or more embodiments, the interlayer insulating layer ILD may be disposed on the gate electrode GE. The interlayer insulating layer ILD may include one of silicon oxide (SiOₓ), silicon nitride (SiNₓ), silicon oxynitride (SiOₓN_{y}), aluminum oxide (AlOₓ), and/or titanium oxide (TiOₓ).

In one or more embodiments, the first transistor electrode TE1 and the second transistor electrode TE2 may be disposed on the interlayer insulating layer ILD. The first transistor electrode TE1 may pass through the gate insulating layer GI and the interlayer insulating layer ILD and contact the first contact area of the active layer ACT, and the second transistor electrode TE2 may pass through the gate insulating layer GI and the interlayer insulating layer ILD and contact the second contact area of the active layer ACT. For example, the first transistor electrode TE1 may be a drain electrode, and the second transistor electrode TE2 may be a source electrode, but the present disclosure is not limited thereto.

In one or more embodiments, the protective layer PSV may be disposed on the first transistor electrode TE1 and the second transistor electrode TE2. The protective layer PSV may include an organic material and/or an inorganic material.

The via layer VIA may be disposed on the protective layer PSV. The via layer VIA may be entirely disposed on the substrate SUB. The via layer VIA may include an organic material. The via layer VIA may provide a flat surface thereon.

The display element layer DPL may be positioned on the via layer VIA.

The display element layer DPL may include first to third bank patterns BNP1 to BNP3, the first alignment electrode ALE1 of the first sub-pixel SPX1, the second alignment electrode ALE2 of the second sub-pixel SPX2, the first insulating layer INS1, the bank BNK, the light emitting elements LD1a, LD1d, LD2b, and LD2c, the first and second pixel electrodes PE1 and PE2, the connection electrodes CNE1 to CNE3, and a color conversion layer CCL.

In one or more embodiments, the first to third bank patterns BNP1 to BNP3 may be disposed on the via layer VIA. The first to third bank patterns BNP1 to BNP3 may protrude in a thickness direction (for example, the third direction DR3) of the via layer VIA, and may have a cross-section of a shape in which a width becomes narrower upward along the third direction DR3. The first to third bank patterns BNP1 to BNP3 may include an organic material and/or an inorganic material.

In one or more embodiments, the first to third bank patterns BNP1 to BNP3 may be used as a reflective member. For example, the first to third bank patterns BNP1 to BNP3 may be used as a reflective member that improves light emission efficiency of the first sub-pixel SPX1 (and/or the second sub-pixel SPX2) by guiding light emitted from each of the light emitting element LD1a, LD1d to a desired direction together with the first alignment electrodes ALE1 (and/or the second alignment electrode ALE2) disposed on the first to third bank patterns BNP1 to BNP3. The first to third bank patterns BNP1 to BNP3 may be integrally formed with the via layer VIA. In another example, the first to third bank patterns BNP1 to BNP3 may be omitted.

In the case of the first sub-pixel SPX1, the (1-1)-th light emitting element LD1a (and the (1-2)-th light emitting element LD1b of FIG. 7) may be disposed between the first bank pattern BNP1 and the second bank pattern BNP2. The (1-4)-th light emitting elements LD1d (and the (1-3)-th light emitting elements LD1c of FIG. 7) may be disposed between the second bank pattern BNP2 and the third bank pattern BNP3. For example, each of the first to third bank patterns BNP1 to BNP3 may define spaces in which the first light emitting element (for example, the first light emitting element LD1 of FIG. 7) is accommodated and arranged.

In the case of the second sub-pixel SPX2, the (2-2)-th light emitting element LD2b (and the (2-1)-th light emitting element LD2a of FIG. 7) may be disposed between the first bank pattern BNP1 and the second bank pattern BNP2. The (2-3)-th light emitting element LD2c (and the (2-4)-th light emitting element LD2d of FIG. 7) may be disposed between the second bank pattern BNP2 and the third bank pattern BNP3. For example, each of the first to third bank patterns BNP1 to BNP3 may define spaces in which the second light emitting element (for example, the second light emitting element LD2 of FIG. 7) is accommodated and arranged.

In one or more embodiments, the first alignment electrode ALE1 of the first sub-pixel SPX1 and the second alignment electrode ALE2 of the second sub-pixel SPX2 may be disposed on the via layer VIA. Each of the first alignment electrode ALE1 and the second alignment electrode ALE2 may be disposed on the via layer VIA and the first to third bank patterns BNP1 to BNP3.

In another example, the third bank pattern BNP3 of the first sub-pixel SPX1 may be integrally formed with the first bank pattern BNP1 of the second sub-pixel SPX2. In this case, the bank BNK may be disposed on the third bank pattern BNP3 of the first sub-pixel SPX1 and the first bank pattern BNP1 of the second sub-pixel SPX2.

The first and second alignment electrodes ALE1 and ALE2 may include a conductive material. For example, the first and second alignment electrodes ALE1 and ALE2 may include one of silver (Ag), magnesium (Mg), aluminum (Al), platinum (Pt), palladium (Pd), gold (Au), nickel (Ni), neodymium (Nd), iridium (Ir), chromium (Cr), titanium (Ti), and/or an alloy thereof. However, the first and second alignment electrodes ALE1 and ALE2 are not limited to the above-described example.

In one or more embodiments, the first insulating layer INS1 may be disposed on the via layer VIA and the first and second alignment electrodes ALE1 and ALE2. The first insulating layer INS1 may cover the first and second alignment electrodes ALE1 and ALE2. The first insulating layer INS1 may stabilize a connection between electrode configurations and reduce an external influence. The first insulating layer INS1 may include an organic material and/or an inorganic material. In an example, the first insulating layer INS1 may include one of silicon oxide (SiOₓ), silicon nitride (SiNₓ), silicon oxynitride (SiOₓN_{y}), aluminum oxide (AlOₓ), and/or titanium oxide (TiOₓ). In another example, the first insulating layer INS1 may include polyimide (PI).

In one or more embodiments, the first insulating layer INS1 may include first and second openings OP1 and OP2. The first opening OP1 may overlap the first emission area EMA1. The second opening OP2 may overlap the second emission area EMA2. In an example, the (1-1)-th opening OP1a and the (2-1)-th opening OP2a may be disposed between the first bank pattern BNP1 and the second bank pattern BNP2. The (1-2)-th opening OP1b and the (2-2)-th opening OP2b may be disposed between the second bank pattern BNP2 and the third bank pattern BNP3.

The (1-1)-th light emitting element LD1a (and the (1-2)-th light emitting element LD1b of FIG. 7) may be disposed on the (1-1)-th opening OP1a, and the (1-4)-th light emitting elements LD1d (and the (1-3)-th light emitting elements LD1c of FIG. 7) may be disposed on the (1-2)-th opening OP1b.

The (2-2)-th light emitting element LD2b (and the (2-1)-th light emitting element LD2a of FIG. 7) may be disposed on the (2-1)-th opening OP2a, and the (2-3)-th light emitting elements LD2c (and the (2-4)-th light emitting elements LD2d of FIG. 7) may be disposed on the (2-2)-th opening OP2b.

An insulating pattern INP may be provided and/or formed under the light emitting elements LD1a, LD1d, LD2b, and LD2c. The insulating pattern INP may be disposed on the first insulating layer INS1. Before the insulating pattern INP is formed, a void (an empty space) may be formed between the first and second openings OP1 and OP2 of the first insulating layer INS1 and the light emitting elements LD1a, LD1d, LD2b, and LD2c. The void may be filled in a process of forming the insulating pattern INP. Accordingly, the insulating pattern INP may prevent a portion of the light emitting elements LD1a, LD1d, LD2b, and LD2c from being disposed across a step of the first insulating layer INS1 formed in the first and second openings OP1 and OP2, and may stably fix the light emitting elements LD1a, LD1d, LD2b, and LD2c.

In one or more embodiments, the insulating pattern INP may include a material different from that of the first insulating layer INS1, but is not limited thereto, and the insulating pattern INP may have the same material as the first insulating layer INS1.

In one or more embodiments, the bank BNK may be disposed on the first insulating layer INS1. The bank BNK may protrude in a thickness direction of the substrate SUB. The bank BNK may have a shape surrounding the first and second emission areas EMA1 and EMA2. According to one or more embodiments, the bank BNK may include an organic material and/or an inorganic material. The bank BNK may correspond to the non-emission area NEA.

In one or more embodiments, the first light emitting element LD1 may be supplied and aligned in the first emission area EMA1 of the first sub-pixel SPX1 in which the first insulating layer INS1 and the bank BNK are formed. For example, the first light emitting elements LD1 may be supplied (or input) to the first emission area EMA1 through an inkjet printing method or the like and the first light emitting element LD1 may be aligned on the first alignment electrode ALE1 by an electric field formed by suitable signals (e.g., a predetermined signals or alignment signals) applied to each of the first and second alignment electrodes ALE1 and ALE2. For example, the first light emitting elements LD1 may be aligned on the first opening OP1 of the first insulating layer INS1.

In one or more embodiments, the second light emitting element LD2 may be supplied and aligned in the second emission area EMA2 of the second sub-pixel SPX2 in which the first insulating layer INS1 and the bank BNK are formed. For example, the second light emitting elements LD2 may be supplied (or input) to the second emission area EMA2 through an inkjet printing method or the like, and the second light emitting element LD2 may be aligned on the second alignment electrode ALE2 by an electric field formed by suitable signals (e.g., predetermined signals or alignment signals) applied to the first and second alignment electrodes ALE1 and ALE2. For example, the second light emitting elements LD2 may be aligned on the second opening OP2 of the first insulating layer INS1.

In one or more embodiments, the first light emitting element LD1 may overlap the first alignment electrode ALE1, and the second light emitting element LD2 may overlap the second alignment electrode ALE2.

In one or more embodiments, the second insulating layer INS2 may be disposed on each of the first and second light emitting elements LD1 and LD2. The second insulating layer INS2 may cover active layers (for example, the active layer 12 of FIG. 1) of the first and second light emitting elements LD1 and LD2. In addition, the second insulating layer INS2 may prevent a short between adjacent electrodes (for example, a short between the first and second pixel electrodes PE1 and PE2 and the connection electrodes CNE1 to CNE3). The second insulating layer INS2 may include an organic material or an inorganic material.

The first and third connection electrodes CNE1 and CNE3 may be disposed on the first insulating layer INS1 and the second insulating layer INS2.

In the first sub-pixel SPX1, the first connection electrode CNE1 may contact the second end of the (1-1)-th light emitting element LD1a, and in the second sub-pixel SPX2, the first connection electrode CNE1 may contact the first end of the (2-2)-th light emitting element LD2b.

In the first sub-pixel SPX1, the third connection electrode CNE3 may contact the first end of the (1-4)-th light emitting element LD1d, and in the second sub-pixel SPX2, the third connection electrode CNE3 may contact the second end of the (2-3)-th light emitting element LD2c.

In one or more embodiments, the third insulating layer INS3 may be disposed on the first connection electrode CNE1 and the third connection electrode CNE3, and may be disposed between the first pixel electrode PE1 and the first connection electrode CNE1, between the first and second connection electrodes CNE1 and CNE2, between the second and third connection electrodes CNE2 and CNE3, and between the second pixel electrode PE2 and the third connection electrode CNE3. An electrical short between the first pixel electrode PE1 and the first connection electrode CNE1, between the first and second connection electrodes CNE1 and CNE2, between the second and third connection electrodes CNE2 and CNE3, and between the second pixel electrode PE2 and the third connection electrode CNE3 may be prevented.

In one or more embodiments, the third insulating layer INS3 may include at least one material selected from among silicon oxide (SiOₓ), silicon nitride (SiNₓ), silicon oxynitride (SiOₓN_{y}), aluminum oxide (AlOₓ), and/or titanium oxide (TiOₓ).

The first and second pixel electrodes PE1 and PE2 and the second connection electrode CNE2 may be disposed on the first to third insulating layers INS1 to INS3.

In the first sub-pixel SPX1, the first pixel electrode PE1 may contact the first end of the (1-1)-th light emitting element LD1a. In the first sub-pixel SPX1, the second pixel electrode PE2 may contact the second end of the (1-4)-th light emitting element LD1d.

In the second sub-pixel SPX2, the second connection electrode CNE2 may contact the second end of the (2-2)-th light emitting element LD2b and the first end of the (2-3)-th light emitting element LD2c.

The first pixel electrode PE1 may be an anode electrode electrically connected to the first transistor T1. The second pixel electrode PE2 may be a cathode electrode electrically connected to the second power line (for example, the second power line PL2 of FIG. 4).

In one or more embodiments, the first and second pixel electrodes PE1 and PE2 and the connection electrodes CNE1 to CNE3 may include a conductive material. For example, the first and second pixel electrodes PE1 and PE2 and the connection electrodes CNE1 to CNE3 may include a transparent conductive material including one of indium tin oxide (ITO), indium zinc oxide (IZO), and/or indium tin zinc oxide (ITZO). However, the present disclosure is not necessarily limited to the above-described example.

In one or more embodiments, the fourth insulating layer INS4 may be directly disposed on the first insulating layer INS1 disposed on the second bank pattern BNP2. The fourth insulating layer INS4 disposed on the first sub-pixel SPX1 may prevent an electrical short between the first pixel electrode PE1 and the third connection electrode CNE3 and between the first connection electrode CNE1 and the second connection electrode CNE2. The fourth insulating layer INS4 disposed on the second sub-pixel SPX2 may prevent an electrical short between the second connection electrode CNE2 and the third connection electrode CNE3 and between the first connection electrode CNE1 and the second pixel electrode PE2.

In one or more embodiments, a fifth insulating layer INS5 may cover the first and second pixel electrodes PE1 and PE2, the second connection electrode CNE2, and a fourth insulating layer INS4. The fifth insulating layer INS5 may protect lower configurations of the display element layer DPL.

In one or more embodiments, the fifth insulating layer INS5 may include at least one material selected from among silicon oxide (SiOₓ), silicon nitride (SiNₓ), silicon oxynitride (SiOₓN_{y}), aluminum oxide (AlOₓ), and/or titanium oxide (TiOₓ).

In one or more embodiments, the color conversion layer CCL may be disposed on the fifth insulating layer INS5. The color conversion layer CCL may change or transmit a wavelength of light provided from the first light emitting element LD1 and the second light emitting element LD2 of the first sub-pixel SPX1 and the second sub-pixel SPX2.

When the first sub-pixel SPX1 is a red pixel, a wavelength conversion pattern WCP of the color conversion layer CCL may include first color conversion particles (for example, a quantum dot) that convert first color light (blue light) emitted from the first light emitting element LD1 into red light. The first color conversion particle may emit the red light by absorbing the first color light and shifting a wavelength according to an energy transition.

When the second sub-pixel SPX2 is a green pixel, the wavelength conversion pattern WCP of the color conversion layer CCL may include second color conversion particles (for example, a quantum dot) that convert the first color light emitted from the second light emitting element LD2 into green light. The second color conversion particle may emit the green light by absorbing the first color light and shifting a wavelength according to an energy transition.

Although only a cross-sectional view of the first and second sub-pixels SPX1 and SPX2 is shown in FIG. 8, when the third sub-pixel SPX3 is a blue pixel, the wavelength conversion pattern WCP of the color conversion layer CCL may include third color conversion particles (for example, a quantum dot) that convert the first color light emitted from the third light emitting element LD3 into blue light. The third color conversion particle may absorb the light of the first color and emit blue light by shifting a wavelength according to an energy transition.

In one or more embodiments, the color conversion particle may have a shape of spherical, pyramidal, multi-arm, cubic nanoparticle, nanotube, nanowire, nanofiber, nanoplate particle, or the like, but is not limited thereto.

In one or more embodiments, the optical layer OPL may be disposed on the display element layer DPL. According to one or more embodiments, the optical layer OPL may include a first capping layer CAP1, a low refraction layer LRL, and a second capping layer CAP2.

In one or more embodiments, the first capping layer CAP1 may seal (or cover) the color conversion layer CCL. The first capping layer CAP1 may be disposed between the low refraction layer LRL and the display element layer DPL. The first capping layer CAP1 may prevent permeation of an impurity such as moisture or air from the outside. For example, the first capping layer CAP1 may include one of silicon nitride (SiNx), silicon oxide (SiOx), silicon oxynitride (SiOxNy), and/or aluminum oxide (AlOx).

In one or more embodiments, the low refraction layer LRL may be disposed between the first capping layer CAP1 and the second capping layer CAP2. The low refraction layer LRL may improve light efficiency by recycling light provided from the color conversion layer CCL. To this end, the low refraction layer LRL may have a refractive index lower than that of the color conversion layer CCL. In an example, the low refraction layer LRL may include a base resin and a hollow particle dispersed in the base resin. The hollow particles may include a hollow silica particle. Alternatively, the hollow particle may be a pore formed by porogen, but is not limited thereto. In addition, the low refraction layer LRL may include one of zinc oxide (ZnOx), titanium oxide (TiOx), and/or nano silicate particles, but is not limited thereto.

In one or more embodiments, the second capping layer CAP2 may be disposed on the low refraction layer LRL. The second capping layer CAP2 may prevent permeation of an impurity such as moisture or air from the outside. The second capping layer CAP2 may include one of silicon nitride (SiNx), silicon oxide (SiOx), silicon oxynitride (SiOxNy), and/or aluminum oxide (AlOx).

In one or more embodiments, a color filter layer CFL may be disposed on the second capping layer CAP2. The color filter layer CFL may include color filters CF1 to CF3 and an overcoat layer OC.

In one or more embodiments, a first color filter CF1 may be disposed over the first emission area EMA1 and the non-emission area NEA in correspondence with a color of the first sub-pixel SPX1. The first color filter CF1 may transmit light of the color of the first sub-pixel SPX1 and does not transmit light of a color of the second and third sub-pixels SPX2 and SPX3. In one or more embodiments, the first color filter CF1, a second color filter CF2, and a third color filter CF3 may be sequentially stacked in the non-emission area NEA.

In one or more embodiments, the overcoat layer OC may be disposed on the color filters CF. The overcoat layer OC may prevent moisture or air from permeating into a lower member. In addition, the overcoat layer OC may protect the above-described lower member from a foreign substance such as dust. In an example, the overcoat layer OC may include an organic material such as acrylates resin, epoxy resin, phenol resin, polyamide resin, polyimide resin, polyester resin, polyphenylenesulfide resin, and/or benzocyclobutene (BCB). However, the present disclosure is not necessarily limited to the above-described example.

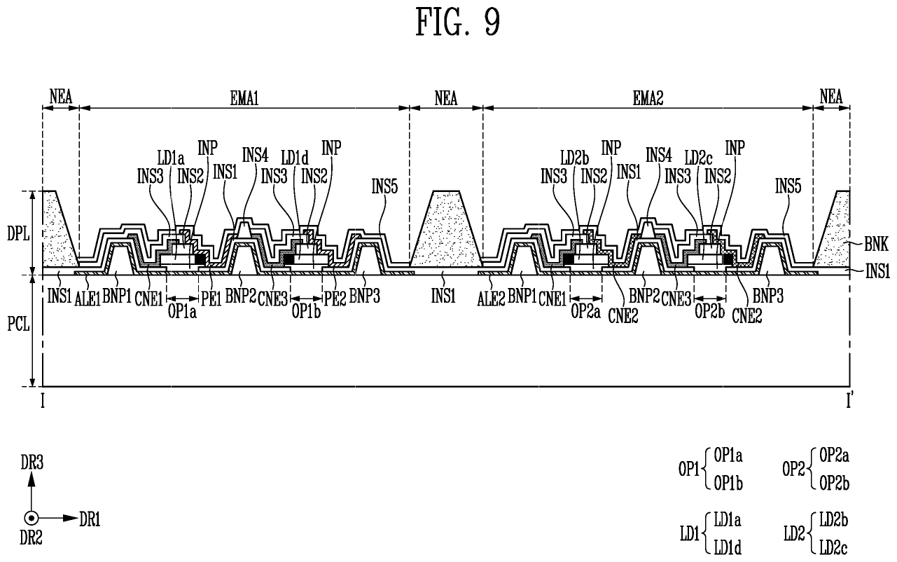

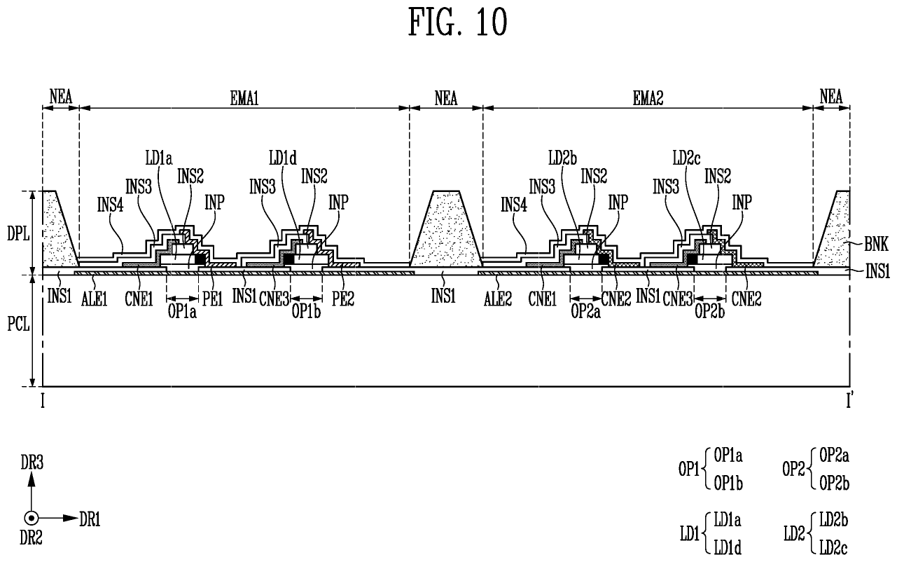

FIGS. 9 and 10 are schematic cross-sectional views illustrating another embodiment taken along the line I-I′ of FIGS. 6 and 7.

Referring to FIG. 9, configurations except for the display element layer DPL including the color conversion layer CCL shown in FIG. 8, the optical layer OPL, and the color filter layer CFL correspond to configurations shown in FIG. 8. The same reference numerals are used for corresponding components and a repetitive description is omitted.

Referring to FIG. 9, the wavelength conversion pattern WCP may be omitted from the display element layer DPL, and in this case, a light transmission pattern layer may be disposed. In an example, the optical layer OPL and the color filter layer CFL may be selectively applied on the display element layer DPL.

The first light emitting element LD1 of the first sub-pixel SPX1 and the second light emitting element LD2 of the second sub-pixel SPX2 may emit blue light, and when the first sub-pixel SPX1 (and/or the second sub-pixel SPX2) is a blue pixel, a light transmission pattern layer may be disposed on the display element layer DPL instead of the color conversion layer. The light transmission pattern layer may be for efficiently using light emitted from the first light emitting element LD1 (and/or the second light emitting elements LD2), and may include a plurality of light scattering particles dispersed in a suitable matrix material (e.g., a predetermined matrix material) such as a base resin. For example, the light transmission pattern layer may include light scattering particles such as silica, but a configuration material of the light scattering particles is not limited thereto.

Referring to FIG. 10, configurations except for the display element layer DPL including the first to third bank patterns BNP1, BNP2, and BNP3 and the color conversion layer CCL shown in FIG. 8, the optical layer OPL, and the color filter layer CFL correspond to configurations shown in FIG. 8. The same reference numerals are used for corresponding components and a repetitive description is omitted.

The display element layer DPL shown in FIG. 10 may be a display element layer from which the first to third bank patterns BNP1 to BNP3 are omitted based on FIG. 9. Similar to this, also with reference to FIG. 8, the display element layer DPL shown in FIG. 10 may be a display element layer from which the first to third bank patterns BNP1 to BNP3 are omitted. The first and second alignment electrodes ALE1 and ALE2 may be directly disposed on the pixel circuit layer PCL (for example, the via layer VIA of FIG. 8).

The first insulating layer INS1 may be entirely disposed on the first and second alignment electrodes ALE1 and ALE2. The first insulating layer INS1 may include a first opening OP1 and a second opening OP2. The first opening OP1 may be disposed in the first emission area EMA1, and the second opening OP2 may be disposed in the second emission area EMA2.

The first opening OP1 may define an area where the first light emitting element LD1 is arranged. The second opening OP2 may define an area where the second light emitting element LD2 is arranged.

FIG. 11A is a cross-sectional view illustrating a comparative example of the sub-pixels included in the display device.

The comparative example according to FIG. 11A may include first to seventh alignment electrodes ALE1′ to ALE7′. The first to seventh alignment electrodes ALE1′ to ALE7′ may be disposed to be spaced from each other in the first direction DR1.

The first sub-pixel SPX1 may include the first to third alignment electrodes ALE1′ to ALE3′, the second sub-pixel SPX2 may include the third to fifth alignment electrodes ALE3′ to ALE5′, and the third sub-pixel SPX3 may include the fifth to seventh alignment electrodes ALE5′ to ALE7′. In an example, the first and second sub-pixels SPX1 and SPX2 may share the third alignment electrode ALE3′, and the second and third sub-pixels SPX2 and SPX3 may share the fifth alignment electrode ALE5′.

The first to seventh alignment electrodes ALE1′ to ALE7′ may be covered by an insulating layer INS. The insulating layer INS does not include an opening.

In the alignment process, a control signal may be applied to the first to seventh alignment electrodes ALE1′ to ALE7′. The first, third, and fifth alignment electrodes ALE1′, ALE3′, and ALE5′ may receive the first alignment signal, and the second and fourth alignment electrodes ALE2′ and ALE4′ may receive the second alignment signal different from the first alignment signal.

A portion of the first light emitting element LD1 of the first sub-pixel SPX1 may be disposed between the first and second alignment electrodes ALE1′ and ALE2′ by a first electric field IEL1 formed between (or on) the first alignment electrode ALE1′ and the second alignment electrode ALE2′. A remaining portion of the first light emitting element LD1 of the first sub-pixel SPX1 may be disposed between the second and third alignment electrodes ALE2′ and ALE3′ by a second electric field IEL2 formed between (or on) the second alignment electrode ALE2′ and the third alignment electrode ALE3′.

In the process of aligning the light emitting elements, a parasitic electric field occurring due to the elements included in the pixel circuit layer PCL may not be shielded, due to a separation space formed between the first alignment electrode ALE1′ and the second alignment electrode ALE2′ and formed between the second alignment electrode ALE2′ and the third alignment electrode ALE3′. Therefore, an electric field formed between the alignment electrodes ALE1′ to ALE7′ may be distorted due to the parasitic electric field, and thus the light emitting elements LD1 to LD3 may not be aligned between (or on) the alignment electrodes ALE1′ to ALE7′.

FIG. 11B is a schematic cross-sectional view illustrating an embodiment of the sub-pixels included in the display device of FIG. 3.

The display element layer DPL (refer to FIGS. 8 to 10) of the display device of FIG. 11B may include the first to third alignment electrodes ALE1 to ALE3. The first to third alignment electrodes ALE1 to ALE3 may be disposed to be spaced from each other in the first direction DR1.

The first sub-pixel SPX1 may include the first alignment electrode ALE1, the second sub-pixel SPX2 may include the second alignment electrode ALE2, and the third sub-pixel SPX3 may include the third alignment electrode ALE3.

The first insulating layer INS1 may be entirely disposed on the first to third alignment electrodes ALE1 to ALE3 of the first to third sub-pixels SPX1 to SPX3. The first insulating layer INS1 may include a first opening OP1 in an area corresponding to the first sub-pixel SPX1, a second opening OP2 in an area corresponding to the second sub-pixel SPX2, and a third opening OP3 in an area corresponding to the third sub-pixel SPX3.

A separation space between the first alignment electrode ALE1 and the second alignment electrode ALE2 and a separation space between the second alignment electrode ALE2 and the third alignment electrode ALE3 may overlap the bank BNK at a lower portion of the bank BNK.

In the alignment process, a control signal may be applied to the first to third alignment electrodes ALE1 to ALE3. The first and third alignment electrodes ALE1 and ALE3 may receive the first alignment signal, and the second alignment electrode ALE2 may receive the second alignment signal different from the first alignment signal.

When the control signal is applied to the first alignment electrode ALE1 and the second alignment electrode ALE2, the first electric field IEL1 may be formed, and the first electric field IEL1 may be concentrated to the (1-2)-th opening OP1b and the (2-1)-th opening OP2a. Accordingly, a portion of the first light emitting element LD1 may be disposed on the (1-2)-th opening OP1b, and a portion of the second light emitting element LD2 may be disposed on the (2-1)-th opening OP2a.

When the control signal is applied to the second alignment electrode ALE2 and the third alignment electrode ALE3, the second electric field IEL2 may be formed, and the second electric field IEL2 may be concentrated to the (2-2)-th opening OP2b and the (3-1)-th opening OP3a. Accordingly, the rest of the second light emitting element LD2 may be disposed on the (2-2)-th opening OP2b, and a portion of the third light emitting element LD3 may be disposed on the (3-1)-th opening OP3a.

As the respective first to third alignment electrodes ALE1 to ALE3 are disposed to cover the first to third emission areas EMA1 to EMA3, and a separation space between the first to third alignment electrodes ALE1 to ALE3 overlaps the bank BNK, the parasitic electric field occurring in the pixel circuit layer PCL may be effectively shielded, and thus a uniform electric field may be formed.

Therefore, in the alignment process of the first to third light emitting elements LD1 to LD3, distortion of the first electric field IEL1 and the second electric field IEL2 formed between the first to third alignment electrodes ALE1 to ALE3 due to the parasitic electric field may be prevented (or minimized). That is, the respective first to third light emitting elements LD1 to LD3 may be normally aligned on the first to third alignment electrodes ALE1 to ALE3.

In addition, as the first electric field IEL1 and the second electric field IEL2 formed between the first to third alignment electrodes ALE1 to ALE3 through the first to third openings OP1 to OP3 formed in the first insulating layer INS1 are concentrated, the respective first to third light emitting elements LD1 to LD3 may be arranged along the first to third openings OP1 to OP3.

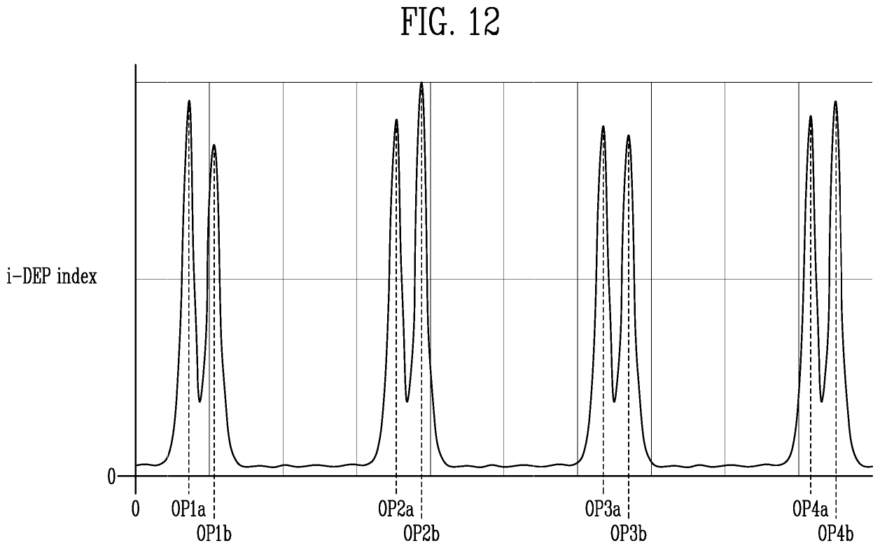

FIG. 12 is a graph illustrating an electric field intensity on the first insulating layer of FIG. 11B.

Referring to FIGS. 11B and 12, FIG. 12 illustrates an electric field intensity (i-dielectrophoresis (DEP) index) measured on the first insulating layer INS1 by the first and second electric fields IEL1 and IEL2 when the first electric field IEL1 and the second electric field IEL2 are formed between the first to third alignment electrodes ALE1, ALE2, and ALE3 by applying an alignment signal to the first to third alignment electrodes ALE1, ALE2, and ALE3.

An intensity of the electric field measured in an area where the first to third openings OP1 to OP3 are formed included in the first insulating layer INS1 is 12 to 50 times higher than an electric field measured in an area of the first insulating layer INS1 where the first to third openings OP1 to OP3 are not formed. That is, an electric field by the first electric field IEL1 and the second electric field IEL2 is concentrated to the first to third openings OP1 to OP3. The electric field may increase as a difference of a dielectric constant between a material of the first insulating layer INS1 and a solvent of the ink for providing the light emitting element increases. The difference of the dielectric constant may be increased by the first to third openings OP1 to OP3 formed in the first insulating layer INS1. In an example, as a thickness of the first insulating layer INS1 increases, the electric field may increase, and conversely, as the thickness of the first insulating layer INS1 decreases, the electric field may decrease. In order to form an appropriate electric field, the thickness of the first insulating layer INS1 is required to be 0.2 μm or more. In addition, in consideration of another configuration (for example, the bank BNK), a maximum thickness of INS1 may be 2 μm or less.

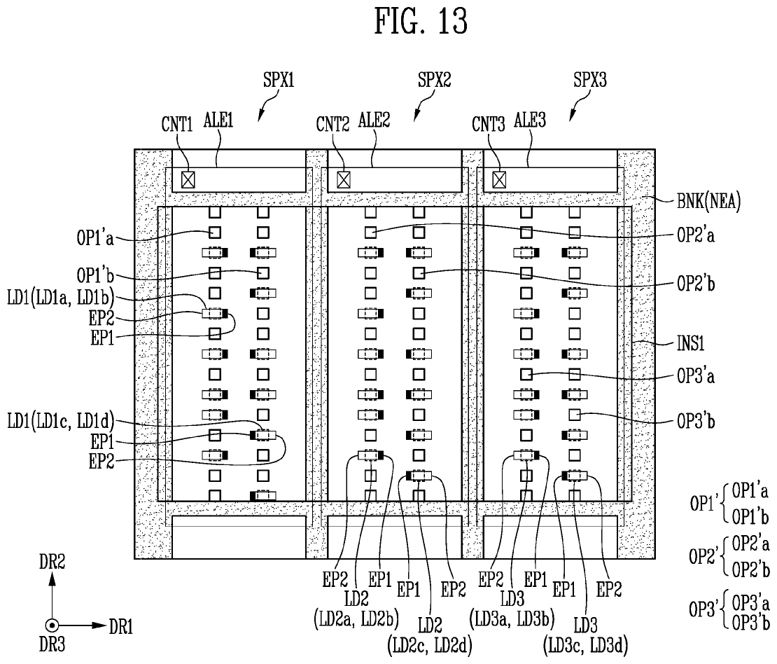

FIGS. 13 to 15 are schematic plan views illustrating another embodiment of the sub-pixels included in the display device of FIG. 3.

Referring to FIG. 13, remaining configurations except for the first to third openings OP1 to OP3 shown in FIG. 6 correspond to configurations shown in FIG. 6. The same reference numerals are used for corresponding components and a repetitive description is omitted.

In one or more embodiments, the first insulating layer INS1 may include first to third openings OP1′ to OP3′. The first opening OP1′ may overlap the first emission area EMA1. The second opening OP2′ may overlap the second emission area EMA2. The third opening OP3′ may overlap the third emission area EMA3.

In one or more embodiments, each of the first to third openings OP1′ to OP3′ may include a plurality of openings (or sub-openings) arranged along the second direction DR2.

The first opening OP1′ may include (1-1)-th openings OP1′a and (1-2)-th openings OP1′b. The (1-1)-th openings OP1′a may be disposed to be spaced from the (1-2)-th openings OP1′b in the first direction DR1. The (1-2)-th openings OP1′bmay be disposed adjacent to the second alignment electrode ALE2. The (1-1)-th openings OP1′a may be disposed adjacent to the third alignment electrode ALE3 included in a pixel adjacent to the corresponding pixel PLX. Each of the (1-1)-th openings OP1′a and the (1-2)-th openings OP1′b may include a plurality of openings, and the plurality of openings may be disposed to be spaced from each other in the second direction DR2.

The second opening OP2′ may include (2-1)-th openings OP2′a and (2-2)-th openings OP2′b. The (2-1)-th openings OP2′a may be disposed to be spaced from the (2-2)-th openings OP2′b in the first direction DR1. The (2-1)-th openings OP2′a may be disposed adjacent to the first alignment electrode ALE1. The (2-2)-th openings OP2′b may be disposed adjacent to the third alignment electrode ALE3. Each of the (2-1)-th openings OP2′a and (2-2)-th openings OP2′b may include a plurality of openings, and the plurality of openings may be disposed to be spaced from each other in the second direction DR2.

The third opening OP3′ may include (3-1)-th openings OP3′a and (3-2)-th openings OP3′b. The (3-1)-th openings OP3′a may be disposed to be spaced from the (3-2)-th openings OP3′b in the first direction DR1. The (3-1)-th openings OP3′amay be disposed adjacent to the second alignment electrode ALE2. The (3-2)-th openings OP3′b may be disposed adjacent to the first alignment electrode ALE1 included in a pixel adjacent to the corresponding pixel PLX. Each of the (3-1)-th openings OP3′a and the (3-2)-th openings OP3′b may include a plurality of openings, and the plurality of openings may be disposed to be spaced from each other in the second direction DR2.

As each of the first to third openings OP1′ to OP3′ includes a pattern in which a plurality of openings are arranged along the second direction DR2, the first to third light emitting elements LD1 to LD3 may be prevented from being aggregated or biasedly disposed in one area in the alignment process of the first to third light emitting elements LD1 to LD3.

In one or more embodiments, when the first electric field is formed between the first alignment electrode ALE1 and the second alignment electrode ALE2 in the alignment process of the first to third light emitting elements LD1 to LD3, the first electric field may be concentrated through the (1-2)-th openings OP1′b and the (2-1)-th openings OP2′a. In this case, the (1-4)-th light emitting element LD1d may be disposed in an area corresponding to an opening pattern of the (1-2)-th openings OP1′b. That is, as the (1-4)-th light emitting element LD1d is disposed in the area corresponding to the opening pattern of the (1-2)-th openings OP1′b, the (1-4)-th light emitting element LD1d may be prevented from being arranged in a gathered state. In addition, the (2-2)-th light emitting element LD2b may be disposed in an area corresponding to an opening pattern of the (2-1)-th openings OP2′a. That is, as the (2-2)-th light emitting element LD2b is disposed in the area corresponding to the opening pattern of the (2-2)-th openings OP2′a, the (2-2)-th light emitting element LD2b may be prevented from being arranged in a gathered state.

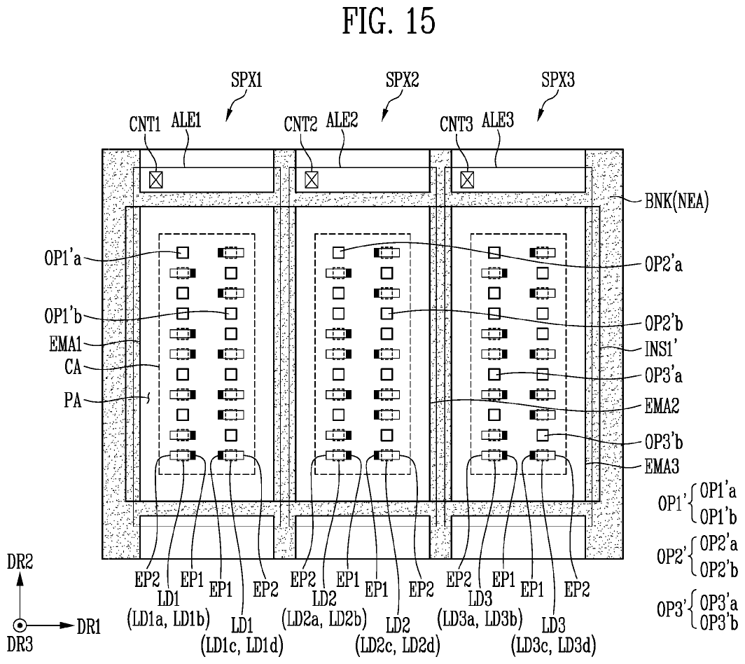

Referring to FIGS. 14 and 15, remaining configurations except for the first insulating layer INS1 shown in FIG. 6 correspond to configurations shown in FIG. 6. The same reference numerals are used for corresponding components and a repetitive description is omitted.

In one or more embodiments, a first insulating layer INS1′ may be disposed to cover the first to third emission areas EMA1 to EMA3.

Referring to FIGS. 5, 14, and 15, in FIG. 14, the first insulating layer INS1′ is disposed to overlap the first to fourth vertical extension portions VBNK1 to VBNK4 and the first to third emission areas EMA1, EMA2, and EMA3, but may be disposed to entirely cover the bank BNK and the first to third alignment electrodes ALE1 to ALE3.

Referring to FIG. 14, the first insulating layer INS1′ may include first to third openings OP1 to OP3. Each of the first to third openings OP1 to OP3 may be disposed to overlap the central area CA, and the first to third openings OP1 to OP3 may not overlap the peripheral area PA. In an example, each of the first to third openings OP1 to OP3 may be one opening extending across the central area CA in the second direction DR2.

Referring to FIG. 15, the first insulating layer INS1′ may include first to third openings OP1′ to OP3′. Each of the first to third openings OP1′ to OP3′ may be disposed to overlap the central area CA, and the first to third openings OP1′ to OP3′ may not overlap the peripheral area PA. In an example, each of the first to third openings OP1′ to OP3′ may include a plurality of openings arranged in the second direction DR2 in the central area CA.

The first light emitting element LD1 may be disposed on the first openings P1 and OP1′. The second light emitting element LD2 may be disposed on the second openings OP2 and OP2′. The third light emitting element LD3 may be disposed on the third openings OP3 and OP3′. The respective first to third light emitting elements LD1 to LD3 may be centrally disposed in the central area CA of the first to third emission areas EMA1 to EMA3.

The first to third light emitting elements LD1 to LD3 disposed in the peripheral area PA may be in a defective state (for example, non-emission) due to an influence (for example, a parasitic electric field and/or a parasitic capacitor) of various lines and circuit elements disposed under the bank BNK (or an area overlapping the non-emission area NEA). Therefore, as the first to third light emitting elements LD1 to LD3 are centrally disposed in the central area CA, an influence of peripheral lines and circuit elements may be reduced or minimized to reduce the number of light emitting elements in a defective state, thereby increasing light emission efficiency.

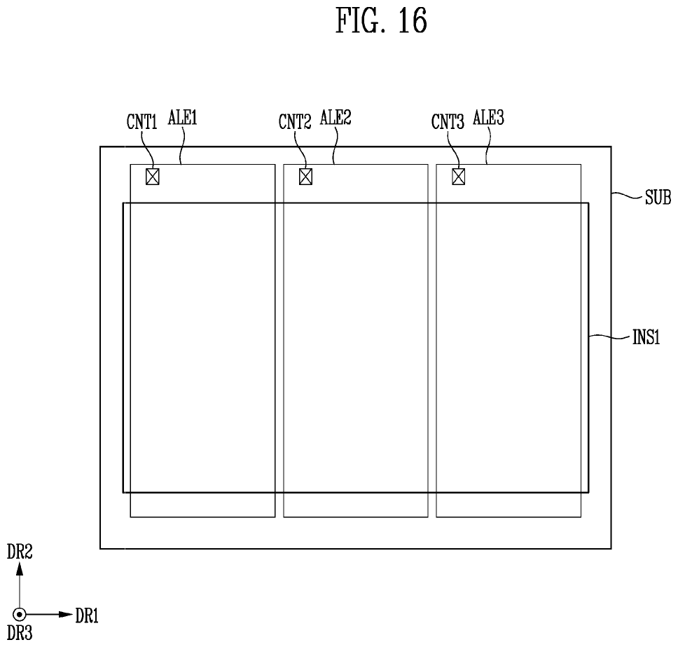

FIGS. 16 to 19 are schematic plan views illustrating a method of manufacturing a display device according to one or more embodiments of the present disclosure.

In the present disclosure, a manufacturing step of the pixel PXL is described as being sequentially performed according to a cross-sectional view, unless the spirit of the disclosure is changed, it is obvious that some steps shown as being successively performed may be performed concurrently (e.g., simultaneously), an order of each step may be changed, some steps may be omitted, or another step may be further included between each step.

In FIGS. 16 to 19, in order to avoid a repetitive description, a point different from that of the above-described embodiment is mainly described.

Referring to FIG. 16, the method of manufacturing the display device may include forming the first to third alignment electrodes ALE1 to ALE3 disposed to be spaced from each other in the first direction DR1 on the substrate SUB, and forming the first insulating layer INS1 to cover one area of the first to third alignment electrodes ALE1 to ALE3 (or the entire surface of the substrate SUB).

As shown in FIG. 16, the first to third alignment electrodes ALE1 to ALE3 may be formed on the substrate SUB. For example, the first to third alignment electrodes ALE1 to ALE3 may be formed through patterning of a conductive material using a mask. Each of the first to third alignment electrodes ALE1 to ALE3 may be connected to a signal line to which a corresponding alignment signal is transmitted through corresponding contact holes CNT1 to CNT3.

As shown in FIG. 16, after the first to third alignment electrodes ALE1 to ALE3 are formed on the substrate SUB, the first insulating layer INS1 may be applied to cover one area of the first to third alignment electrodes ALE1 to ALE3 (or the entire surface of the substrate SUB).

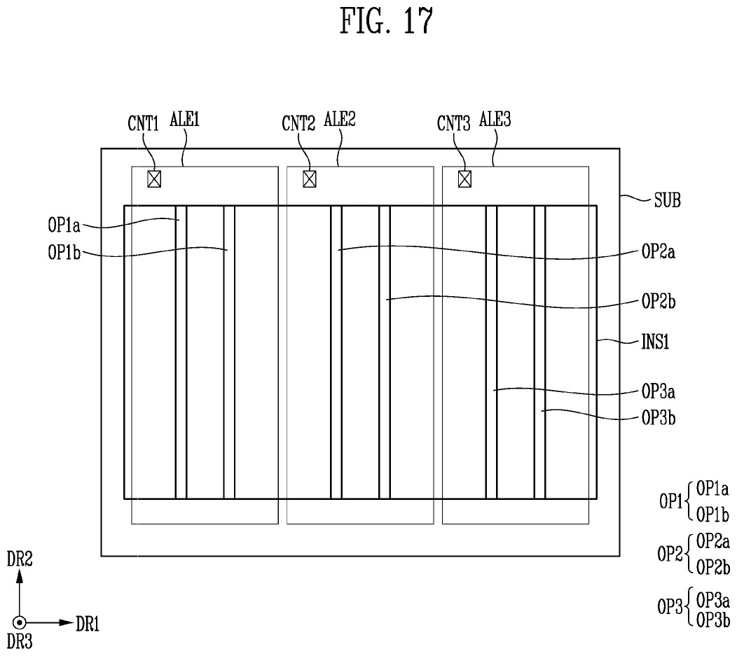

Referring to FIG. 17, the method of manufacturing the display device may include forming the first opening OP1 exposing the first alignment electrode ALE1, the second opening OP2 exposing the second alignment electrode ALE2, and the third opening OP3 exposing the third alignment electrode ALE3.

The first opening OP1 may be formed by removing an area of the first insulating layer INS1 overlapping the first alignment electrode ALE1 using a patterning and etching process. The (1-2)-th opening OP1b may be formed to be spaced from the (1-1)-th opening OP1a in the first direction DR1. Each of the (1-1)-th opening OP1a and the (1-2)-th opening OP1b may extend in the second direction DR2 to expose the first alignment electrode ALE1 through one opening, but is not limited thereto. The embodiments of FIGS. 13 to 15 may be applied. For example, each of the (1-1)-th opening OP1a and the (1-2)-th opening OP1b may include a plurality of openings sequentially arranged in the second direction DR2. In one or more embodiments, the second opening OP2 and the third opening OP3 may be formed in the same method as the first opening OP1, but are not limited thereto.

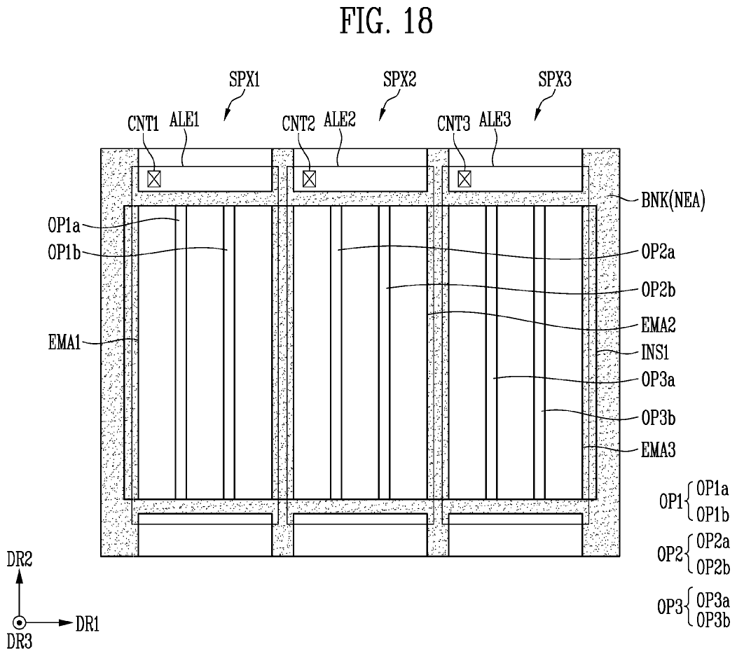

Referring to FIG. 18, the method of manufacturing the display device may include forming the bank BNK defining the first to third emission areas EMA1 to EMA3 on the first to third alignment electrodes ALE1 to ALE3 and the first insulating layer INS1.

As shown in FIG. 18, the bank BNK defining the first emission area EMA1 of the first sub-pixel SPX1, the second emission area EMA2 of the second sub-pixel SPX2, and the third emission area EMA3 of the third sub-pixel SPX3 may be formed. The bank BNK may be formed by patterning an organic material including a light blocking material using a mask. In an example, the first to third openings OP1 to OP3 may be formed to cover the first to third emission areas EMA1 to EMA3, respectively.

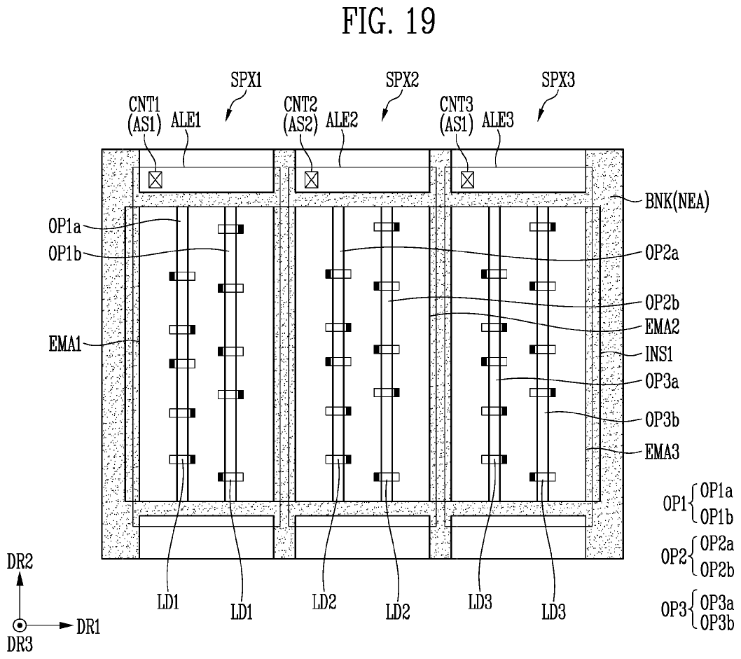

Referring to FIG. 19, the method of manufacturing the display device may include providing the first to third light emitting elements LD1 to LD3 in the first emission area EMA1, the second emission area EMA2, and the third emission area EMA3, and arranging the first to third light emitting elements LD1 to LD3 using the alignment signal.

As shown in FIG. 19, the first light emitting element LD1 may be provided in the first emission area EMA1. The second light emitting element LD2 may be provided in the second emission area EMA2. The third light emitting element LD3 may be provided in the third emission area EMA3. In an example, an ink of a volatile solvent including the first, second, and third light emitting elements LD1, LD2, and LD3 may be input to each of the first, second, and third emission areas EMA1, EMA2, and EMA3, which are spaces defined by the bank BNK. The first, second, and third light emitting elements LD1, LD2, and LD3 may be input through an inkjet printing method, a slit coating method, or various other methods. The solvent of the ink may include at least one of propylene glycol methyl ether acetate (PGMEA), propylene glycol monomethyl ether (PGME), and/or propylene glocol (PG).

As shown in FIG. 19, after the first, second, and third light emitting elements LD1, LD2, and LD3 are provided in the first, second, and third emission areas EMA1, EMA2, and EMA3, respectively, a first alignment signal AS1 may be applied to the first alignment electrode ALE1 and the third alignment electrode ALE3, and a second alignment signal AS2 may be applied to the second alignment electrode ALE2. As the alignment signal is applied to the first to third alignment electrodes ALE1 to ALE3, the first light emitting element LD1 may be aligned on the first opening OP1, the second light emitting element LD2 may be aligned on the second opening OP2, and the third light emitting element LD3 may be aligned on the third opening OP3 (refer to FIG. 6).

The display device and the method of manufacturing the same according to one or more embodiments of the present disclosure may dispose one alignment electrode per sub-pixel and dispose a boundary area between alignment electrodes in an area overlapping the non-emission area. Accordingly, the display device and the method of manufacturing the same may effectively shield a parasitic electric field due to the pixel circuit to reduce or minimize a light emitting element in a defective state occurring due to the parasitic electric field, thereby increasing light emission efficiency.

In addition, the display device and the method of manufacturing the same according to one or more embodiments of the present disclosure may allow an electric field formed between the alignment electrodes to be concentrated in an opening formed in an insulating layer. Accordingly, because the light emitting elements may be accurately aligned, the display device and the method of manufacturing the same according to one or more embodiments may increase light emission efficiency.

Although the present disclosure has been described with reference to the embodiments thereof, those skilled in the art will understand that the present disclosure may be variously modified and changed without departing from the spirit and scope of the present disclosure disclosed in the following claims and their equivalents.

What is claimed is:

1. A display device comprising:
a substrate including a first emission area and a second emission area spaced from the first emission area in a first direction;
a bank partitioning the first emission area and the second emission area;
a first alignment electrode covering the first emission area in a plan view;
a second alignment electrode spaced from the first alignment electrode and covering the second emission area in a plan view;
first light emitting elements on the first alignment electrode; and
second light emitting elements on the second alignment electrode.

2. The display device according to claim 1, wherein the first alignment electrode is configured to receive a first alignment signal and the second alignment electrode is configured to receive a second alignment signal, and
wherein the first alignment signal is different from the second alignment signal.

3. The display device according to claim 2, further comprising:
a third alignment electrode covering a third emission area spaced from the second emission area in the first direction; and
third light emitting elements on the third alignment electrode,
wherein when the first to third light emitting elements are aligned, the third alignment electrode is configured to receive the first alignment signal.

4. The display device according to claim 1, further comprising:
an insulating layer covering the first alignment electrode and the second alignment electrode,
wherein the insulating layer comprises:
at least one first opening overlapping the first emission area; and
at least one second opening overlapping the second emission area.

5. The display device according to claim 4, wherein the first light emitting elements are on the at least one first opening, and
wherein the second light emitting elements are on the at least one second opening.

6. The display device according to claim 5, further comprising:
an insulating pattern filling the at least one first opening and the at least one second opening,
wherein the first light emitting elements are directly located on a portion of the insulating pattern, and
the second light emitting elements are directly located on another portion of the insulating pattern.

7. The display device according to claim 5, wherein each of the first emission area and the second emission area includes a central area and a peripheral area surrounding the central area,
wherein the at least one first opening is in an area corresponding to the central area of the first emission area, and
wherein the at least one second opening is in an area corresponding to the central area of the second emission area.

8. The display device according to claim 7, wherein the at least one first opening and the at least one second opening are not in the peripheral area.

9. The display device according to claim 8, wherein each of the at least one first opening and the at least one second opening is one opening extending in a second direction crossing the first direction in the central area.

10. The display device according to claim 8, wherein the at least one first opening includes a plurality of first openings and the at least one second opening includes a plurality of second openings,
wherein the first openings are spaced from each other in a second direction crossing the first direction, and
wherein the second openings are spaced from each other in the second direction.

11. The display device according to claim 5, wherein the at least one first opening crosses the first emission area along a second direction crossing the first direction.

12. The display device according to claim 11, wherein each of the at least one first opening and the at least one second opening is one opening extending in the second direction.

13. The display device according to claim 11, wherein the at least one first opening includes a plurality of first openings and the at least one second opening includes a plurality of second openings that are spaced from each other,
wherein the first openings are spaced from each other in the second direction, and
wherein the second openings are spaced from each other in the second direction.

14. The display device according to claim 4, wherein the at least one first opening comprises:
at least one (1-1)-th opening extending in a second direction crossing the first direction; and
at least one (1-2)-th opening spaced from the at least one (1-1)-th opening in the first direction, and
wherein the at least one second opening comprises:
at least one (2-1)-th opening extending in the second direction; and
at least one (2-2)-th opening spaced from the at least one (2-1)-th opening in the first direction.

15. The display device according to claim 14, wherein a portion of the first light emitting elements is on the at least one (1-1)-th opening,
wherein a rest of the first light emitting elements is on the at least one (1-2)-th opening,
wherein a portion of the second light emitting elements is on the at least one (2-1)-th opening, and
wherein a rest of the second light emitting elements is on the at least one (2-2)-th opening.

16. The display device according to claim 15, wherein each of the first light emitting elements and the second light emitting elements comprises a first end and a second end opposite the first end, and
wherein the first end of the first light emitting elements on the at least one (1-1)-th opening faces the first end of the first light emitting elements on the at least one (1-2)-th opening, in a plan view.

17. The display device according to claim 16, wherein the first light emitting elements on the at least one (1-2)-th opening have a same orientation as the second light emitting elements on the at least one (2-1)-th opening.

18. The display device according to claim 1, wherein a boundary area between the first alignment electrode and the second alignment electrode is under the bank, and
wherein an area of the first alignment electrode is equal to an area of the second alignment electrode.

19. The display device according to claim 1, wherein each of the first light emitting elements and the second light emitting elements comprise a first end and a second end opposite the first end, and wherein the display device further comprises a first pixel electrode, a connection electrode, and a second pixel electrode in each of the first emission area and the second emission area, spaced from each other in the first direction, and sequentially arranged,
wherein the first pixel electrode is connected to the first end of a portion of the first light emitting elements,
wherein the connection electrode connects the second end of the portion of the first light emitting elements and the first end of a rest of the first light emitting elements, and
wherein the second pixel electrode is connected to the second end of the rest of the first light emitting elements.

20. A method of manufacturing a display device, the method comprising:
forming a first alignment electrode covering a first emission area of a substrate and a second alignment electrode covering a second emission area of the substrate spaced from the first emission area in a first direction;
forming an insulating layer covering the first and second alignment electrodes;
forming at least one first opening exposing the first alignment electrode and at least one second opening exposing the second alignment electrode in the insulating layer;
forming a bank on a boundary area between the first alignment electrode and the second alignment electrode;
providing light emitting elements to the first emission area and the second emission area; and
arranging the first and second light emitting elements by applying a first alignment signal to the first alignment electrode and a second alignment signal different from the first alignment signal to the second alignment electrode.
